(19) United States
(12) Patent Application Publication
(10) Pub. No.: US 2025/0120081 A1
(43) Pub. Date: Apr. 10, 2025

(54) SEMICONDUCTOR DEVICE AND ELECTRONIC SYSTEM INCLUDING THE SAME

(71) Applicant: SAMSUNG ELECTRONICS CO., LTD., SUWON-SI (KR)

(72) Inventors: Hyunjun AHN, Suwon-si (KR); Hanhim KANG, Suwon-si (KR); Donghwan LEE, Suwon-si (KR)

(21) Appl. No.: 18/761,611

(22) Filed: Jul. 2, 2024

(30) Foreign Application Priority Data
Oct. 4, 2023 (KR) 10-2023-0131944

(51) Int. Cl. H10B 43/27; H10B 41/27; H10B 41/41; H10B 43/40

(52) U.S. Cl. CPC H10B 43/27; H10B 41/27; H10B 41/41; H10B 43/40

(57) ABSTRACT

A semiconductor device includes: a mold structure; and a first high aspect ratio via disposed in a second via hole which passes through at least a portion of the mold structure, wherein the low aspect ratio via includes a first seed pattern, which is disposed in the first via hole, and a first conductive pattern that is disposed on the first seed pattern, wherein the first high aspect ratio via includes a second seed pattern, which is disposed in the second via hole, a second conductive pattern, which is disposed on the second seed pattern, a deposition inhibition pattern, which covers at least a portion of the second conductive pattern, and a third conductive pattern, which covers the deposition inhibition pattern, and wherein the deposition inhibition pattern includes a material which is less in surface free energy than the second conductive pattern.

### CROSS-REFERENCE TO RELATED APPLICATION

This application claims priority under 35 U.S.C. § 119 to Korean Patent Application No. 10-2023-0131944, filed on Oct. 4, 2023, in the Korean Intellectual Property Office, the disclosure of which is incorporated by reference herein in its entirety.

### TECHNICAL FIELD

Embodiments of the present inventive concept relate to a semiconductor device and an electronic system including the same.

### DISCUSSION OF THE RELATED ART

Generally, electronic systems that use data storage need semiconductor devices for storing a high amount of data, and thus, a method of increasing the data storage capacity of semiconductor devices is currently under development. For example, to increase the data storage capacity of semiconductor devices, semiconductor devices including vertical memory devices, which include three-dimensionally arranged memory cells instead of two-dimensionally arranged memory cells, have been under development.

### SUMMARY

According to embodiments of the present inventive concept, a semiconductor device includes: a mold structure; a low aspect ratio via disposed in a first via hole that passes through at least a portion of the mold structure; and a first high aspect ratio via disposed in a second via hole which passes through at least a portion of the mold structure and is spaced apart from the first via hole in a horizontal direction, wherein the low aspect ratio via includes a first seed pattern, which is disposed in the first via hole, and a first conductive pattern that is disposed on the first seed pattern, wherein the first high aspect ratio via includes a second seed pattern, which is disposed in the second via hole, a second conductive pattern, which is disposed on the second seed pattern, a deposition inhibition pattern, which covers at least a portion of an inner sidewall of the second conductive pattern, and a third conductive pattern, which covers an inner sidewall of the deposition inhibition pattern, and wherein the deposition inhibition pattern includes a material which is less in surface free energy (SFE) than the second conductive pattern.

According to embodiments of the present inventive concept, a semiconductor device includes: an upper substrate; a memory stack structure including a plurality of gate lines overlapping each other in a vertical direction with respect to an upper surface of the upper substrate; a channel structure passing through the memory stack structure; a memory cell contact disposed in a first hole passing through at least one of the plurality of gate lines, wherein the memory cell contact contacts one gate line selected from among the plurality of gate lines in the first hole and is spaced apart from the other gate line except the selected one gate line; a bit line extending in a horizontal direction on the memory stack structure; and a stud connecting the channel structure with the bit line, wherein the stud includes a first conductive pattern and a first seed pattern surrounding the first conductive pattern, wherein the memory cell contact includes a second seed pattern, which is disposed in the first hole, a second conductive pattern, which is disposed on the second seed pattern, a first deposition inhibition pattern, which covers at least a portion of an inner sidewall of the second conductive pattern, and a third conductive pattern, which covers an inner sidewall of the first deposition inhibition pattern, and wherein the first deposition inhibition pattern includes a material which is less in surface free energy than the second conductive pattern.

According to embodiments of the present inventive concept, an electronic system includes: a main substrate; a semiconductor device disposed on the main substrate; and a controller electrically connected with the semiconductor device on the main substrate, wherein the semiconductor device includes: an upper substrate; a memory stack structure including a plurality of gate lines overlapping each other in a vertical direction with respect to an upper surface of the upper substrate; a channel structure passing through the memory stack structure; and a memory cell contact disposed in a first hole that passes through at least one of the plurality of gate lines, wherein the memory cell contact contacts one gate line selected from among the plurality of gate lines in the first hole and is spaced apart from the other gate line except the selected one gate line, wherein the memory cell contact includes a seed pattern, which is disposed in the first hole, a first conductive pattern, which is disposed on the seed pattern, a deposition inhibition pattern, which covers at least a portion of an inner sidewall of the first conductive pattern, and a second conductive pattern, which covers an inner sidewall of the deposition inhibition pattern, and wherein the deposition inhibition pattern includes a tapered shape, wherein a width of the deposition inhibition pattern in a horizontal direction is progressively reduced as the deposition inhibition pattern extends downward in the vertical direction with respect to an upper surface of the mold structure.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view illustrating a portion of a semiconductor device according to embodiments of the present inventive concept;

FIG. 2A is an enlarged cross-sectional view of some elements included in a region PP1 of FIG. 1;

FIG. 2B is an enlarged cross-sectional view of some elements included in a region PP2 of FIG. 1;

FIG. 3A is a plan view of an upper surface of a low aspect ratio via of FIG. 1;

FIG. 3B is a plan view of an upper surface of a first high aspect ratio via of FIG. 1;

FIG. 3C is a plan view of an upper surface of a second high aspect ratio via of FIG. 1;

FIGS. 4A, 4B, 4C and 4D are cross-sectional views illustrating a method of manufacturing a semiconductor device, according to embodiments of the present inventive concept;

FIG. 5 is a cross-sectional view illustrating a semiconductor device according to embodiments of the present inventive concept;

FIGS. 6A, 6B, and 6C are cross-sectional views illustrating a method of manufacturing a semiconductor device, according to embodiments of the present inventive concept;

FIG. 7 is a block diagram of a semiconductor device according to embodiments of the present inventive concept;

FIG. 8 is a schematic perspective view of a semiconductor device according to embodiments of the present inventive concept;

FIG. 9 is a circuit diagram of a memory cell array of a semiconductor device according to embodiments of the present inventive concept;

FIG. 10 is a schematic plan view of a partial region of a semiconductor device according to embodiments of the present inventive concept;

FIG. 11 is a schematic plan view of some elements of a memory cell block included in a semiconductor device according to embodiments of the present inventive concept;

FIG. 12A is a cross-sectional view taken along line X1-X1′ of FIG. 11;

FIG. 12B is a cross-sectional view taken along line Y1-Y1′ of FIG. 11;

FIG. 13A is an enlarged cross-sectional view of some elements included in a region PP3 of FIG. 12A;

FIG. 13B is a plan view of an upper surface of a memory cell contact of FIG. 13A;

FIG. 14A is an enlarged cross-sectional view of some elements included in a region PP4 of FIG. 12A;

FIG. 14B is a plan view of an upper surface of a memory through via of FIG. 14A;

FIG. 15A is an enlarged cross-sectional view of some elements included in a region PP5 of FIG. 12B;

FIG. 15B is a plan view of an upper surface of a lower stud of FIG. 15A;

FIG. 16 is an enlarged cross-sectional view of some elements included in a region PP6 of FIG. 12B;

FIG. 17 is a diagram schematically illustrating an electronic system including a semiconductor device, according to embodiments of the present inventive concept;

FIG. 18 is a perspective view schematically illustrating an electronic system including a semiconductor device, according to embodiments of the present inventive concept; and

FIG. 19 is a cross-sectional view schematically illustrating semiconductor packages according to an embodiments of the present inventive concept.

### DETAILED DESCRIPTION OF THE EMBODIMENTS

Hereinafter, embodiments of the present inventive concept will be described in detail with reference to the accompanying drawings. Like reference numerals refer to like elements in the drawings, and their repeated descriptions may be omitted or briefly discussed.

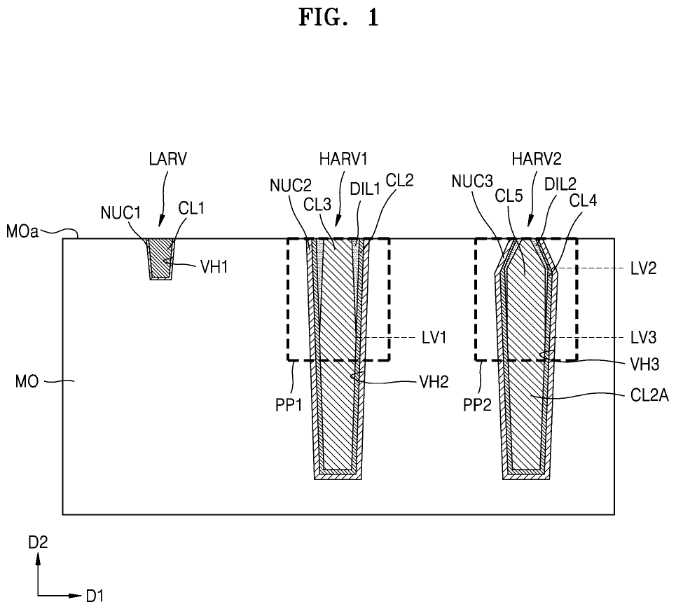

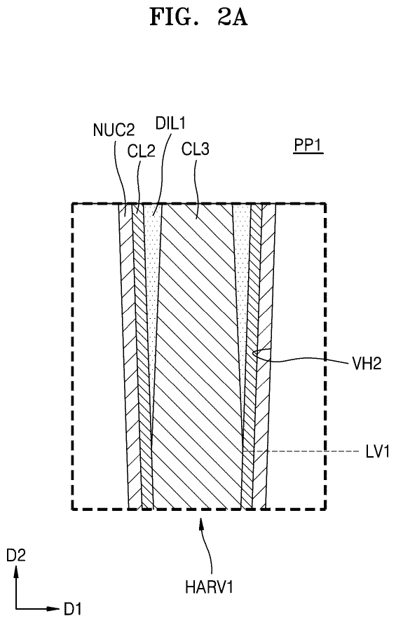

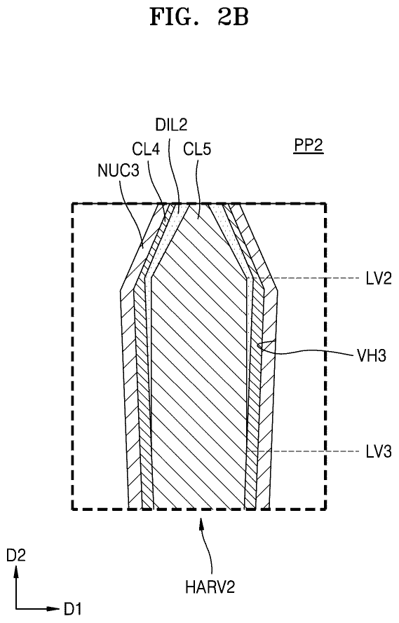

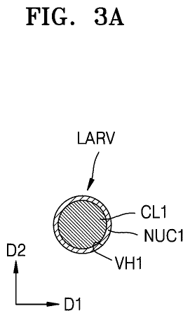

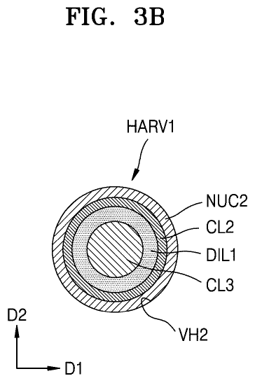

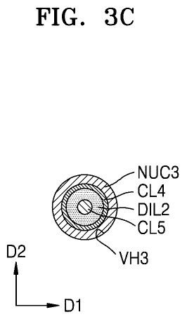

FIG. 1 is a cross-sectional view illustrating a semiconductor device according to embodiments of the present inventive concept. FIG. 2A is an enlarged cross-sectional view of some elements included in a region PP1 of FIG. 1. FIG. 2B is an enlarged cross-sectional view of some elements included in a region PP2 of FIG. 1. FIG. 3A is a plan view of an upper surface of a low aspect ratio via of FIG. 1. FIG. 3B is a plan view of an upper surface of a first high aspect ratio via of FIG. 1. FIG. 3C is a plan view of an upper surface of a second high aspect ratio via of FIG. 1.

Referring to FIG. 1, the semiconductor device 1 may include a mold structure MO, a low aspect ratio via LAR, a first high aspect ratio via HARV1, and a second high aspect ratio via HARV2.

The mold structure MO may include a single layer or a plurality of layers. According to embodiments of the present inventive concept, the mold structure MO may include a semiconductor material, an insulating material, or/and a conductive material. When the mold structure MO includes a plurality of layers, the plurality of layers may include the same material as each other or may include different materials from each other. In addition, the mold structure MO may have a structure where two kinds of materials are alternately and vertically stacked on each other. The semiconductor material may include, for example, silicon (Si), germanium (Ge), silicon germanium (SiGe), gallium arsenic (GaAs), gallium arsenic phosphorus (GaAsP), nitride gallium (GaN), or/and carbide silicon (SiC). For example, the semiconductor material may be single crystalline, polycrystalline, or/and amorphous. The insulating material may include, for example, silicon oxide (SiO₂), silicon nitride (SiN), or/and silicon oxynitride (SiON). The conductive material may include a conductive metal-containing material, conductive metal nitride, or a doped semiconductor material. However, the present inventive concept is not limited thereto.

Herein, a first direction D1 may be one direction parallel to an upper surface MOa of the mold structure MO, and a second direction D2 may be a direction perpendicular to the upper surface MOa of the mold structure MO. Unless specially described, the first direction D1 may be referred to as a horizontal direction, and the second direction D2 may be referred to as a vertical direction.

The low aspect ratio via LARV, the first high aspect ratio via HARV1, and the second high aspect ratio via HARV2 may pass through at least a portion of the mold structure MO. The first high aspect ratio via HARV1 and the second high aspect ratio via HARV2 may extend downward in the second direction D2. The low aspect ratio via LARV may have an aspect ratio of more than 0 and 5 or less and may be a via that has a critical dimension (CD) that is more than 0 kÅ and is about 1 kÅ or less. The first high aspect ratio via HARV1 and the second high aspect ratio via HARV2 may each be a via with an aspect ratio that is 30 or more and a CD that is more than 0 kÅ and that is about 3 kÅ or less. Unless specially described, the low aspect ratio via LARV, the first high aspect ratio via HARV1, and the second high aspect ratio via HARV2 may be referred to as vias.

The low aspect ratio via LARV may be disposed in a first via hole VH1 passing through at least a portion of the mold structure MO. The low aspect ratio via LARV may include a first seed pattern NUC1, which covers an inner sidewall of the first via hole VH1, and a first conductive pattern CL1 that is disposed on the first seed pattern NUC1. The first seed pattern NUC1 may at least partially surround a sidewall and a lower surface of the first conductive pattern CL1. The first seed pattern NUC1 may expose an upper surface of the first conductive pattern CL1. For example, the upper surface of the first conductive pattern CL1 is not covered by the first seed pattern NUC1. The first conductive pattern CL1 may fill all of the other space of the first via hole VH1 except a space where the first seed pattern NUC1 is disposed. The first seed pattern NUC1 may include a metal material. For example, the first seed pattern NUC1 may include tungsten (W), titanium (Ti), aluminum (Al), molybdenum (Mo), tantalum (Ta), palladium (Pd), nickel (Ni), ruthenium (Ru), iridium (Ir), rhodium (Rh), osmium (Os), scandium (Sc), niobium (Nb), copper (Cu), or a combination thereof. The first conductive pattern CL1 may include a material capable of being included in the first seed pattern NUC1. For example, the first conductive pattern CL1 may include the same material as that of the first seed pattern NUC1.

Referring to FIGS. 1 and 2A, the first high aspect ratio via HARV1 may be disposed in a second via hole VH2 that passes through at least a portion of the mold structure MO. The first high aspect ratio via HARV1 may include a second seed pattern NUC2, a second conductive pattern CL2, a first deposition inhibition pattern DIL1, and a third conductive pattern CL3.

The second seed pattern NUC2 may cover an inner sidewall of the second via hole VH2. The second conductive pattern CL2 may be disposed on the second seed pattern NUC2. The first deposition inhibition pattern DIL1 may cover at least a portion of an inner sidewall of the second conductive pattern CL2, on the first high aspect ratio via HARV1.

The first deposition inhibition pattern DILI may have a tapered shape where a horizontal width of the first deposition inhibition pattern DIL1 is progressively reduced as the first deposition inhibition pattern DIL1 extends downward in the second direction D2. The horizontal width of the first deposition inhibition pattern DIL1 may denote a width in the first direction D1. The first deposition inhibition pattern DIL1 may extend downward in the second direction D2 up to a first vertical level LV1 from an uppermost surface of the second conductive pattern CL2. The first vertical level LV1 may be disposed between an upper surface and a lower surface of the first high aspect ratio via HARV1. For example, the first vertical level LV1 may be a vertical level in the first high aspect ratio via HARV1. A vertical level may denote a vertical distance downward in the second direction D2 from the upper surface MOa of the mold structure MO.

The third conductive pattern CL3 may be disposed on the first deposition inhibition pattern DIL1 and the second conductive pattern CL2. The first deposition inhibition pattern DIL1 may be disposed between the second conductive pattern CL2 and the third conductive pattern CL3, between the first vertical level LV1 and the upper surface of the first high aspect ratio via HARV1. The second conductive pattern CL2 and the third conductive pattern CL3 may be spaced apart from each other with the first deposition inhibition pattern DIL1 therebetween, between the first vertical level LV1 and the upper surface of the first high aspect ratio via HARV1. The second seed pattern NUC2 and the third conductive pattern CL3 may be spaced apart from each other with the second conductive pattern CL2 and the first deposition inhibition pattern DIL1 therebetween, between the first vertical level LV1 and the upper surface of the first high aspect ratio via HARV1. The second conductive pattern CL2 may contact the third conductive pattern CL3, between the first vertical level LV1 and the lower surface of the first high aspect ratio via HARV1. The second conductive pattern CL2 may be disposed between the second seed pattern NUC2 and the third conductive pattern CL3, between the first vertical level LV1 and the lower surface of the first high aspect ratio via HARV1. The first deposition inhibition pattern DIL1 may be formed up to only the first vertical level LV1 from the upper surface of the first high aspect ratio via HARV1.

The second seed pattern NUC2 may include a material capable of being included in the first seed pattern NUC1. For example, the second seed pattern NUC2 may include the same material as that of the first seed pattern NUC1. The second conductive pattern CL2 may include a material capable of being included in the first conductive pattern CL1. For example, the second conductive pattern CL2 may include the same material as that of the first conductive pattern CL1. For example, the second conductive pattern CL2 may include the same material as that of the second seed pattern NUC2. The third conductive pattern CL3 may include a material capable of being included in the second conductive pattern CL2. For example, the third conductive pattern CL3 may include the same material as that of the second conductive pattern CL2.

The first deposition inhibition pattern DIL1 may include a material which is lower in surface free energy (SFE) than that of the second seed pattern NUC2. For example, the first deposition inhibition pattern DIL1 may include metal nitride. According to embodiments of the present inventive concept, the first deposition inhibition pattern DIL1 may include tungsten nitride (WN), titanium nitride (TiN), aluminum nitride (AlN), tantalum nitride (TaN), molybdenum nitride (MoN), or a combination thereof. However, this is only an embodiment, and the materials may correspond to a material capable of being included in the first deposition inhibition pattern DIL1 among materials which are lower in SFE than that of the second seed pattern NUC2. SFE of the first deposition inhibition pattern DIL1 may be, for example, more than 0 mJ/m² and less than or equal to about 55 mJ/m². SFE of each of the second seed pattern NUC2 and the second conductive pattern CL2 may be about 1,000 mJ/m² or more.

The reason that the horizontal width of the first deposition inhibition pattern DIL1 is progressively reduced as the first deposition inhibition pattern DIL1 extends downward in the second direction D2 may be based on a feature of a method of forming the first deposition inhibition pattern DIL1. For example, the first deposition inhibition pattern DIL1 may be formed by using a chemical vapor deposition (CVD) process, an atomic layer deposition (ALD) process, a plasma enhanced ALD (PEALD) process, or a combination thereof. The method of forming the first deposition inhibition pattern DIL1 by using the CVD process, the ALD process, and the PEALD process may include a process of supplying two or more kinds of gases at the same time or different times. For example, when the first deposition inhibition pattern DIL1 includes WN, the method of forming the first deposition inhibition pattern DIL1 may include a process of supplying a tungsten hexafluorides (WF₆) pulse while continuously supplying an ammonia (NH₃) gas. Supplying of a pulse may denote a process of supplying a certain gas for a certain time and stopping the supply of the certain gas for another certain time. The supply of a pulse may be performed once or a plurality of times. In a case which supplies the WF₆ pulse in a continuous NH₃ atmosphere, the first deposition inhibition pattern DIL1 may be first formed at an uppermost portion of the first high aspect ratio via HARV1 close to a shower head of each of CVD, ALD, and PEALD equipment. This may be based on the fact that the amount of WF₆ gas that is supplied into a reaction chamber is limited by supplying the WF₆ pulse instead of continuously supplying WF₆. The flow rate, time, or/and number of supply of WF₆ pulse may be adjusted, and thus, the amount of WF₆ gas supplied for each pulse may be adjusted. Therefore, control may be performed so that the amount of reacting WF₆ is progressively reduced as it is provided downward in the second direction D2 from the uppermost surface of the first high aspect ratio HARV1. Based on such a principle, the horizontal width of the first deposition inhibition pattern DIL1 may be progressively reduced as the first deposition inhibition pattern DIL1 extends downward in the second direction D2. In addition, a height of the first vertical level LV1 may be controlled.

In addition, in a case in which WF₆ is supplied as a pulse while continuously supplying NH₃, fluorine (F) impurities that are obtained as a reactant byproduct of NH₃ and WF₆ may be largely reduced. Fluorine may be based on WF₆, and this may be because the amount of WF₆ may be controlled in a case in which WF₆ is supplied as a pulse. Fluorine may be bonded to hydrogen to produce hydrofluoric acid (HF), and HF may damage the mold structure MO. Therefore, in a case in which WF₆ is supplied as a pulse while continuously supplying NH₃, damage to the mold structure MO may be prevented in a subsequent process.

Referring to FIGS. 1 and 2B, the second high aspect ratio via HARV1 may be disposed in a third via hole VH3 that passes through at least a portion of the mold structure MO. The second high aspect ratio via HARV2 may include a third seed pattern NUC3, a fourth conductive pattern CL4, a second deposition inhibition pattern DIL2, and a fifth conductive pattern CL5. The second high aspect ratio via HARV2 may include an upper portion having a negative slope. In other words, a horizontal width of the second high aspect ratio via HARV2 may increase up to a second vertical level LV2 from an upper surface of the second high aspect ratio via HARV2 and may then decrease or be constant from the second vertical level LV2 in the second direction D2. The second vertical level LV2 may be a portion where an angle between a sidewall of the second high aspect ratio via HARV2 and the upper surface MOa of the mold structure MO is rapidly changed.

The third seed pattern NUC3 may cover an inner sidewall of the third via hole VH3. The fourth conductive pattern CL4 may be disposed on the third seed pattern NUC3. The second deposition inhibition pattern DIL2 may cover a portion of an inner sidewall of the fourth conductive pattern CL4, on the second high aspect ratio via HARV2.

The second deposition inhibition pattern DIL2 may have a tapered shape where a horizontal width of the second deposition inhibition pattern DIL2 is progressively reduced as the second deposition inhibition pattern DIL2 extends downward in the second direction D2. The horizontal width of the second deposition inhibition pattern DIL2 may denote a width in the first direction D1. The second deposition inhibition pattern DIL2 may extend downward in the second direction D2 up to a third vertical level LV3 from an uppermost surface of the second high aspect ratio via HARV2. The third vertical level LV3 may be disposed between an upper surface and a lower surface of the second high aspect ratio via HARV2. The third vertical level LV3 may be a vertical level in the second high aspect ratio via HARV2. In FIG. 2B, it is illustrated that the third vertical level LV3 is lower than the second vertical level LV2, but the present inventive concept is not limited thereto, and the third vertical level LV3 may be higher than the second vertical level LV2. A vertical level may denote a vertical distance downward in the second direction D2 from the upper surface MOa of the mold structure MO.

The fifth conductive pattern CL5 may be disposed on the second deposition inhibition pattern DIL2 and the fourth conductive pattern CL4. The second deposition inhibition pattern DIL2 may be disposed between the fourth conductive pattern CL4 and the fifth conductive pattern CL5, between the third vertical level LV3 and the upper surface of the second high aspect ratio via HARV2. The fourth conductive pattern CL4 and the fifth conductive pattern CL5 may be spaced apart from each other with the second deposition inhibition pattern DIL2 therebetween, between the third vertical level LV3 and the upper surface of the second high aspect ratio via HARV2. The third seed pattern NUC3 and the fifth conductive pattern CL5 may be spaced apart from each other with the fourth conductive pattern CL4 and the second deposition inhibition pattern DIL2 therebetween, between the third vertical level LV3 and the upper surface of the second high aspect ratio via HARV2. The fourth conductive pattern CL4 may contact the fifth conductive pattern CL5, between the third vertical level LV3 and the lower surface of the second high aspect ratio via HARV2. For example, the fourth conductive pattern CL4 may be disposed between the third seed pattern NUC3 and the fifth conductive pattern CL5, while contacting the second deposition inhabitation pattern DIL2, between the third vertical level LV3 and the upper surface of the second high aspect ratio via HARV2. For example, the fourth conductive pattern CL4 may be disposed between the third seed pattern NUC3 and the fifth conductive pattern CL5, without contacting the second deposition inhabitation pattern DIL2, between the third vertical level LV3 and the lower surface of the second high aspect ratio via HARV2. The second deposition inhibition pattern DIL2 may be formed up to only the third vertical level LV3 from the upper surface of the second high aspect ratio via HARV2.

The third seed pattern NUC3 may include a material capable of being included in the first seed pattern NUC1. For example, the third seed pattern NUC3 may include the same material as that of the first seed pattern NUC1 or/and the second seed pattern NUC2. The fourth conductive pattern CL4 may include a material capable of being included in the first conductive pattern CL1. For example, the fourth conductive pattern CL4 may include the same material as that of the first conductive pattern CL1 or/and the second conductive pattern CL2. The second deposition inhibition pattern DIL2 may include a material capable of being included in the first deposition inhibition pattern DIL1. For example, the second deposition inhibition pattern DIL2 may include the same material as that of the first deposition inhibition pattern DIL1. The fifth conductive pattern CL5 may include a material capable of being included in the third conductive pattern CL3. For example, the fifth conductive pattern CL5 may include the same material as that of the third conductive pattern CL3. For example, the fifth conductive pattern CL5 may include the same material as that of the third seed pattern NUC3 or/and the fourth conductive pattern CL4.

Referring to FIG. 1, upper surfaces of the first to third seed patterns NUC1 to NUC3, the first to fifth conductive patterns CL1 to CL5, and the first and second deposition inhibition patterns DIL1 and DIL2 may be substantially coplanar.

Referring to FIGS. 1, 3A, 3B, and 3C, from a plan view, the first seed pattern NUC1 of the low aspect ratio via LARV may surround the first conductive pattern CL1 with an annular shape. From a plan view, the second seed pattern NUC2 of the first high aspect ratio via HARV1 may surround the second conductive pattern CL2 with an annular shape, and the second conductive pattern CL2 may surround the first deposition inhibition pattern DIL1 with an annular shape. The first deposition inhibition pattern DIL1 may surround the third conductive pattern CL3 with an annular shape. From a plan view, the third seed pattern NUC3 of the second high aspect ratio via HARV2 may surround the fourth conductive pattern CL4 with an annular shape, and the fourth conductive pattern CL4 may surround the second deposition inhibition pattern DIL2 with an annual shape. The second deposition inhibition pattern DIL2 may surround the fifth conductive pattern CL5 with an annular shape.

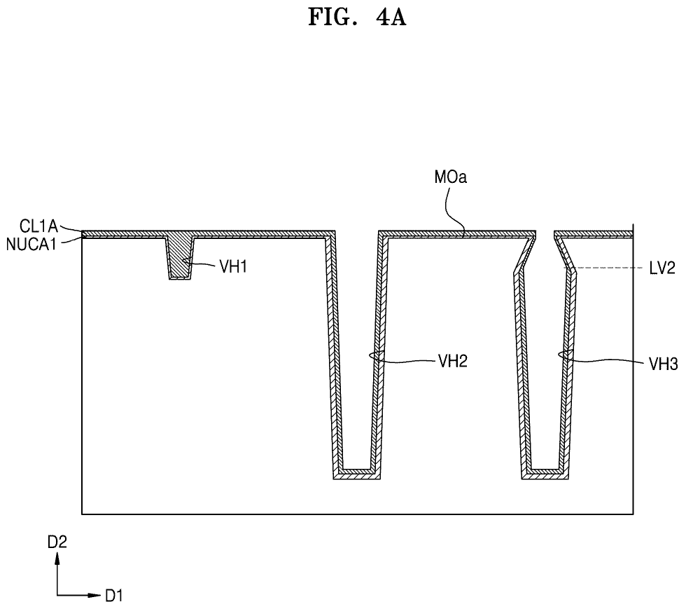

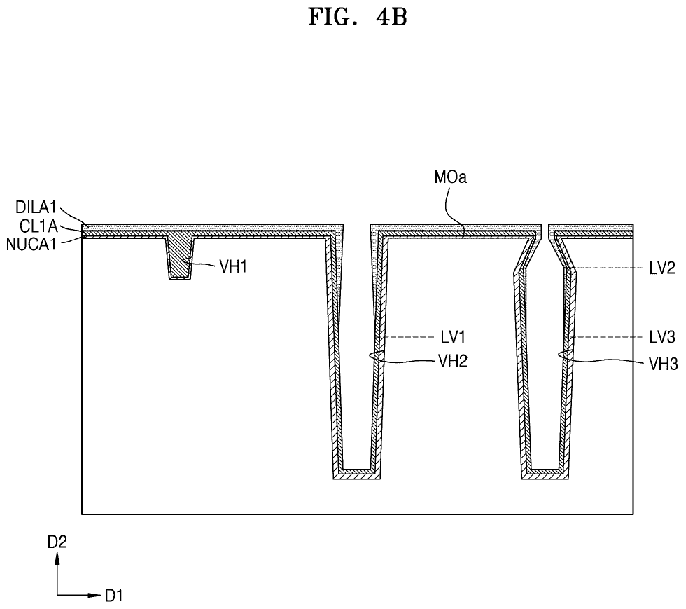

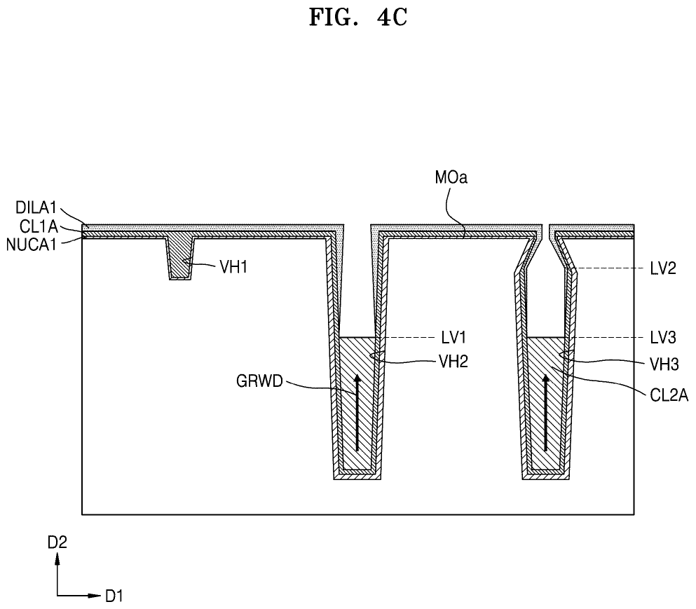

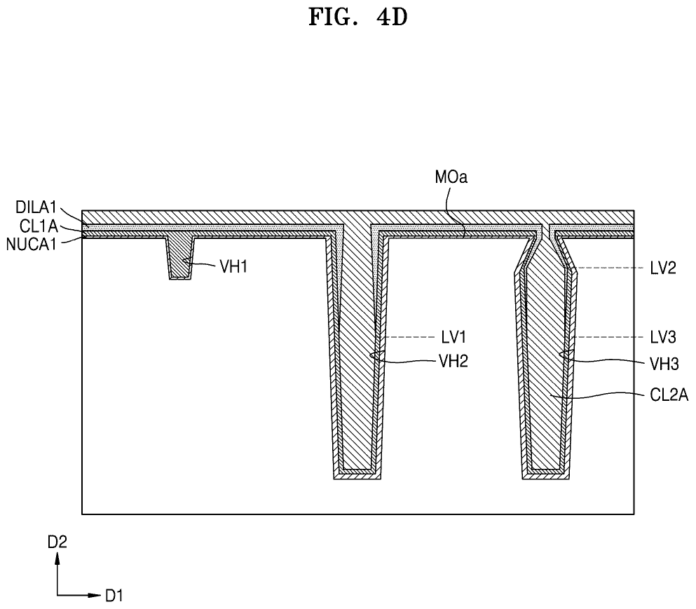

FIGS. 4A to 4D are cross-sectional views illustrating a method of manufacturing a semiconductor device, according to embodiments of the present inventive concept.

Referring to FIG. 4A, a mold structure MO may be provided. The mold structure MO may be formed by using a physical vapor deposition (PVD) process, a CVD process, an ALD process, a PEALD process, or a combination thereof. According to embodiments of the present inventive concept, the mold structure MO may include a semiconductor material, an insulating material, or/and a conductive material. When the mold structure MO includes a plurality of layers, the plurality of layers may include the same material as each other or may include different materials from each other. In addition, the mold structure MO may have a structure where two kinds of materials are alternately and vertically stacked on each other. The semiconductor material may include, for example, Si, Ge, SiGe, GaAs, GaAsP, GaN, or/and SiC. For example, the semiconductor material may be single crystalline, polycrystalline, or/and amorphous. The insulating material may include, for example, SiO₂, SiN, or/and SiON. The conductive material may include a conductive metal-containing material, conductive metal nitride, or a doped semiconductor material. However, this is only an embodiment, and a material included in the mold structure MO is not limited thereto and may include various materials.

A first via hole VH1, a second via hole VH2, and a third via hole VH3 each passing through at least a portion of the mold structure MO may be formed. An aspect ratio of the first via hole VH1 may be more than 0 and less than or equal to 5, and a CD of the first via hole VH1 may be more than 0 kÅ and less than or equal to about 1 kÅ. An aspect ratio of each of the second via hole VH2 and the third via hole VH3 may be 30 or more, and a CD of each of the second via hole VH2 and the third via hole VH3 may be more than 0 kÅ and less than or equal to about 3 kÅ. The first to third via holes VH1 to VH3 may be formed by an etching process. The first to third via holes VH1 to VH3 may be formed at the same time or different times from one another. An inner sidewall of an upper portion of the third via hole VH3 may have a negative slope. For example, a horizontal width of the third via hole VH3 in a horizontal direction may increase up to a second vertical level LV2 from an upper surface MOa of the mold structure MO and may then decrease up to a bottom surface of the third via hole VH3 or may be substantially constant at the second vertical level LV2.

A first seed layer NUCA1 covering inner sidewalls of the first to third via holes VH1 to VH3 may be formed. The first seed layer NUCA1 may be formed on an entire surface of the mold structure MO. The first seed layer NUCA1 may extend up to the upper surface MOa of the mold structure MO from inner sidewalls of the first to third via holes VH1 to VH3. For example, the first seed layer NUCA1 may be formed by a PVD process, a CVD process, an ALD process, a PEALD process, or a combination thereof. As another example, the first seed layer NUCA1 may be formed by using an electro-plating process. The first seed layer NUCA1 may include a metal material. For example, the first seed layer NUCA1 may include W, Ti, Al, Mo, Ta, Pd, Ni, Ru, Ir, Rh, Os, Sc, Nb, Cu, or a combination thereof.

A first conductive layer CL1A may be formed on the first seed layer NUCA1. The first conductive layer CL1A may fill all of the other portion of the first via hole VH1, which is not filled by the first seed layer NUCA1, and may fill only a portion of each of the second via hole VH2 and the third via hole VH3. This may be because the size of the first via hole VH1 is less than that of each of the second via hole VH2 and the third via hole VH3. The first conductive layer CL1A may cover all of an exposed surface of the first seed layer NUCA1. The first conductive layer CL1A may be formed by a PVD process, a CVD process, an ALD process, a PEALD process, or a combination thereof. The first conductive layer CL1A may include a material capable of being included in the first seed layer NUCA1. For example, the first conductive layer CL1A may include the same material as that of the first seed layer NUCA1.

Referring to FIG. 4B, a first deposition inhibition layer DILA1 may be formed on the first conductive layer CL1A. The first deposition inhibition layer DILA1 may cover an uppermost surface of the first conductive layer CL1A. The first deposition inhibition layer DILA1 may cover the first conductive layer CL1A up to a first vertical level LV1, in the second via hole VH2. The first deposition inhibition layer DILA1 may cover the first conductive layer CL1A up to a third vertical level LV3, in the third via hole VH3. In the second via hole VH2 and the third via hole VH3, a horizontal width of the first deposition inhibition layer DILA1 may be progressively reduced as the first deposition inhibition layer DILA1 extends downward in a second direction D2 from the upper surface MOa of the mold structure MO.

The first deposition inhibition layer DILA1 may include a material which is lower in SFE than that of the first seed layer NUCA1. For example, the first deposition inhibition layer DILA1 may include metal nitride. According to embodiments of the present inventive concept, the first deposition inhibition layer DILA1 may include WN, TiN, AlN, TaN, MoN, or a combination thereof. However, this is only an embodiment, and the materials may correspond to a material capable of being included in the first deposition inhibition layer DILA1 among materials which are lower in SFE than that of the first seed layer NUCA1.

A process of forming the first deposition inhibition layer DILA1 may include a CVD process, an ALD process, a PEALD process, or a combination thereof. According to embodiments of the present inventive concept, when the first deposition inhibition layer DILA1 includes WN, the process of forming the first deposition inhibition layer DILA1 may include a process of supplying a WF₆ pulse while continuously supplying an NH₃ gas. Therefore, as a vertical level is lowered from the upper surface MOa of the mold structure MO, a horizontal width of the first deposition inhibition layer DILA1 may decrease.

Referring to FIGS. 4C and 4D, a second conductive layer CL2A may be formed on the first conductive layer CL1A. The second conductive layer CL2A may grow in a growth direction GRWD from a bottom surface of each of the second via hole VH2 and the third via hole VH3. The growth direction GRWD may denote a direction in which the second conductive layer CL2A grows in the second direction D2 from the bottom surface of each of the second via hole VH2 and the third via hole VH3. The second conductive layer CL2A may grow in the growth direction GRWD from the bottom surface of each of the second via hole VH2 and the third via hole VH3 and may fill the remainder of the second via hole VH2 and the third via hole VH3. The second conductive layer CL2A may extend up to an uppermost surface of the first deposition inhibition layer DILA1.

A process where the second conductive layer CL2A grows in the growth direction GRWD may be based on the SFE of the first deposition inhibition layer DILA1 being lower than that of the first conductive layer CL1A. The second conductive layer CL2A may be formed by a CVD process, an ALD process, a PEALD process, or a combination thereof. At this time, a precursor for forming the second conductive layer CL2A may be adsorbed onto a surface having high SFE. Therefore, the precursor for forming the second conductive layer CL2A might not be adsorbed onto the first deposition inhibition layer DILA1 having low SFE and may be well adsorbed onto the first conductive layer CL1A having high SFE. In addition, a process of forming the second conductive layer CL2A at an upper portion, where the first deposition inhibition layer DILA1 is formed, of each of the second and third via holes VH2 and VH3 may be inhibited, and the second conductive layer CL2A may be relatively well formed from a lower portion, on which the first deposition inhibition layer DILA1 is not deposited, of each of the second and third via holes VH2 and VH3.

For example, the growth direction GRWD of the second conductive layer CL2A may be better controlled because the horizontal width of the first deposition inhibition layer DILA1 is progressively reduced as the first deposition inhibition layer DILA1 extends downward in the second direction D2 from the upper surface MOa of the mold structure MO. At a predetermined vertical level, the horizontal width of the first deposition inhibition layer DILA1 being small may denote that the amount of the first deposition inhibition layer DILA1 is low. In addition, as the amount of the deposition inhibition layer DILA1 is reduced, the precursor for forming the second conductive layer CL2A may be better adsorbed. Therefore, the growth direction GRWD of the second conductive layer CL2A may be determined toward a portion, where the amount of the first deposition inhibition layer DILA1 is high, from a portion where the amount of the first deposition inhibition layer DILA1 is low.

For example, when there is no first deposition inhibition layer DILA1 and the horizontal width of the first deposition inhibition layer DILA1 is not reduced downward in the second direction D2 from the upper surface MOa of the mold structure MO, in a case in which a deposition process having step coverage, which is not relatively good, is used, the second conductive layer CL2A may be first formed at the upper portion of each of the second via hole VH2 and the third via hole VH3, and thus, a void may occur in the lower portion of each of the second via hole VH2 and the third via hole VH3. The void may occur in vias which are to be formed later, causing degradation in electrical characteristic and reliability of the semiconductor device 1 of FIG. 1. Even when a deposition process having good step coverage is used, a void may inevitably occur in the lower portion of the third via hole VH3. However, according to embodiments of the present inventive concept, the growth direction GRWD of the second conductive layer CL2A may be controlled, and thus, the void might not be formed. Accordingly, the electrical characteristic and reliability of the semiconductor device 1 of FIG. 1 may be increased.

Referring again to FIG. 1, a planarization process may be performed on the second conductive layer CL2A, the first deposition inhibition layer DILA1, the first conductive layer CL1A, and the first seed layer NUCA1. The planarization process may include, for example, a chemical mechanical polishing (CMP) process. The planarization process may be performed so that the upper surface MOa of the mold structure MO is exposed. The third conductive pattern CL3 and the fifth conductive pattern CL5 may be formed from the second conductive layer CL2A. The first deposition inhibition pattern DIL1 and the second deposition inhibition pattern DIL2 may be formed from the first deposition inhibition layer DILA1. The first conductive pattern CL1, the second conductive pattern CL3, and the fourth conductive pattern CL4 may be formed from the first conductive layer CL1A. The first seed pattern NUC1, the second seed pattern NUC2, and the third seed pattern NUC3 may be formed from the first seed layer NUCA1. Accordingly, the semiconductor device 1 including the low aspect ratio via LARV, the first aspect ratio via HARV1, and the second aspect ratio via HARV2 may be manufactured.

For example, when a process of forming the first conductive layer CL1A is omitted, the first deposition inhibition layer DILA1 may cover the first seed layer NUCA1 of the first via hole VH1 in an operation of forming the first deposition inhibition layer DILA1. In this case, in a process of forming the second conductive layer CL2A in the first via hole VH1, the first deposition inhibition layer DILA1 may be disposed between the first seed layer NUCA1 and the second conductive layer CL2A. In this case, since the first deposition inhibition layer DILA1 may function as a barrier which may hinder flow of a current, electrical characteristics of the semiconductor device 1 may degrade. Therefore, the low aspect ratio via LARV and the first and second aspect ratio vias HARV1 and HARV2 have to be formed separately, causing an increase in the manufacturing cost.

According to embodiments of the present inventive concept, the first conductive layer CL1A may be formed before forming the first deposition inhibition layer DIL1 and the second conductive layer CL2A. The first conductive layer CL1A may fill the first via hole VH1. For example, the first conductive layer CL1A may entirely fill the remaining portion of the first via hole VH1. Accordingly, the first deposition inhibition layer DILA1 might not be formed in the first via hole VH1 in an operation of forming the first deposition inhibition layer DILA1. Therefore, the low aspect ratio via LARV and the first and second aspect ratio vias HARV1 and HARV2 may be simultaneously formed, and thus, the manufacturing cost may be reduced.

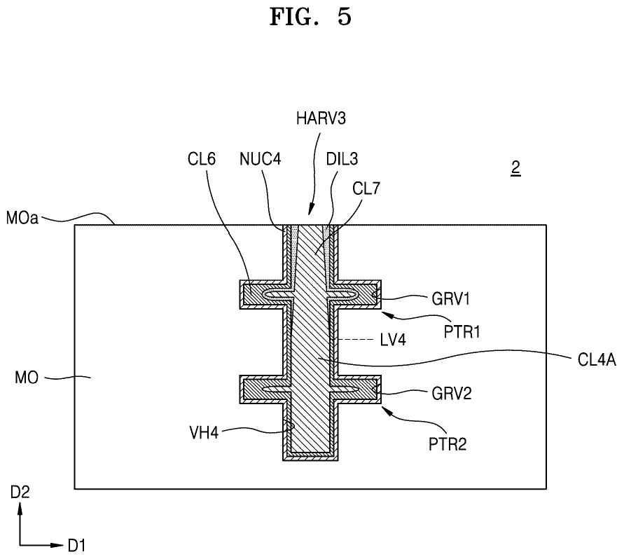

FIG. 5 is a cross-sectional view illustrating a semiconductor device 2 according to embodiments of the present inventive concept.

Referring to FIG. 5, the semiconductor device 2 may include a mold structure MO and a third aspect ratio via HARV3.

The mold structure MO may be provided. A description of the mold structure MO may be the same as the description of the mold structure MO of FIG. 1.

The third aspect ratio via HARV3 may pass through at least a portion of the mold structure MO. The third aspect ratio via HARV3 may extend downward in a second direction D2. The third aspect ratio via HARV3 may have an aspect ratio of 30 or more and may be defined as a via having a CD of more than 0 kÅ and less than or equal to about 3 kÅ.

The third aspect ratio via HARV3 may be disposed in a fourth via hole VH4 that passes through at least a portion of the mold structure MO and first and second grooves GRV1 and GRV2 that are recessed in a first direction D1 from the fourth via hole VH4. The first groove GRV1 and the second groove GRV2 may be at different vertical levels from each other. Only two grooves are illustrated in FIG. 5, but the present inventive concept is not limited thereto and the number of grooves may be one or three or more. The first groove GRV1 may be disposed at a vertical level which is higher than the vertical level at which the second groove GRV2 is disposed. For example, the first groove GRV1 may be closer to the upper surface MOa of the mold structure MO than the second groove GRV2. From a plan view, the first groove GRV1 and the second groove GRV2 may have a polygonal, circular, or oval annular shape. The third aspect ratio via HARV3 may include a first protrusion portion PTR1, which protrudes into the first groove GRV1, and a second protrusion portion PTR2, which protrudes into the second groove GRV2.

The high aspect ratio via HARV3 may include a fourth seed pattern NUC4, a sixth conductive pattern CL6, a third deposition inhibition pattern DIL3, and a seventh conductive pattern CL7.

The fourth seed pattern NUC4 may cover inner sidewalls of the fourth via hole VH4, the first groove GRV1, and the second groove GRV2. The sixth conductive pattern CL6 may be disposed on the fourth seed pattern NUC4. The sixth conductive pattern CL6 may fill at least a portion of the fourth via hole VH4 and at least a portion of each of the first and second grooves GRV1 and GRV2. The third deposition inhibition pattern DIL3 may cover a portion of an inner sidewall of the sixth conductive pattern CL6, in the third high aspect ratio via HARV3. The seventh conductive pattern CL7 may fill the other portions, which are not filled with the fourth seed pattern NUC6, the sixth conductive pattern CL6, and the third deposition inhibition pattern DIL3, of the fourth via hole VH4, the first groove GRV1, and the second groove GRV2.

The third deposition inhibition pattern DIL3 may have a tapered shape where a horizontal width of the third deposition inhibition pattern DIL3 is progressively reduced as the third deposition inhibition pattern DIL3 extends downward in the second direction D2. The third deposition inhibition pattern DIL3 may extend downward in the second direction D2 up to a fourth vertical level LV4 from an uppermost surface of the sixth conductive pattern CL6. The fourth vertical level LV4 may be disposed between an upper surface and a lower surface of the third high aspect ratio via HARV3. The fourth vertical level LV4 may be a predetermined vertical level in the third high aspect ratio via HARV3. The fourth vertical level LV4 may be higher or lower than a vertical level of the first groove GRV1. When the fourth vertical level LV4 is lower than the vertical level of the first groove GRV1, the third deposition inhibition pattern DIL3 may include a portion which extends in a horizontal direction toward the first groove GRV1. In the extended portion, a horizontal width of the third deposition inhibition pattern DIL3 may denote a thickness of the extended portion in a direction perpendicular to the normal line at an arbitrary point of the extended portion.

The seventh conductive pattern CL7 may be disposed on the third deposition inhibition pattern DIL3 and the sixth conductive pattern CL6. The third deposition inhibition pattern DIL3 may be disposed between the sixth conductive pattern CL6 and the seventh conductive pattern CL7, between the fourth vertical level LV4 and an upper surface of the third high aspect ratio via HARV3. The sixth conductive pattern CL6 and the seventh conductive pattern CL7 may be spaced apart from each other with the third deposition inhibition pattern DIL3 therebetween, between the fourth vertical level LV4 and the upper surface of the third high aspect ratio via HARV3. The fourth seed pattern NUC4 and the seventh conductive pattern CL7 may be spaced apart from each other with the sixth conductive pattern CL6 and the third deposition inhibition pattern DIL3 therebetween, between the fourth vertical level LV4 and the upper surface of the third high aspect ratio via HARV3. The sixth conductive pattern CL6 may contact the seventh conductive pattern CL7, between the fourth vertical level LV4 and a lower surface of the third high aspect ratio via HARV3. The sixth conductive pattern CL6 may be disposed between the fourth seed pattern NUC4 and the seventh conductive pattern CL7, between the fourth vertical level LV4 and the lower surface of the third high aspect ratio via HARV3. The third deposition inhibition pattern DIL3 may be formed up to only the fourth vertical level LV4 from the upper surface of the third high aspect ratio via HARV3.

The fourth seed pattern NUC4 may include a material capable of being included in the first seed pattern NUC1 of FIG. 1. The sixth conductive pattern CL6 may include a material capable of being included in the first conductive pattern CL1 of FIG. 1. For example, the sixth conductive pattern CL6 may include the same material as that of the fourth seed pattern NUC4. The third deposition inhibition pattern DIL3 may include a material capable of being included in the first deposition inhibition pattern DIL1 of FIG. 1. The seventh conductive pattern CL7 may include a material capable of being included in the first conductive pattern CL1 of FIG. 1. For example, the seventh conductive pattern CL7 may include the same material as that of the sixth conductive pattern CL6.

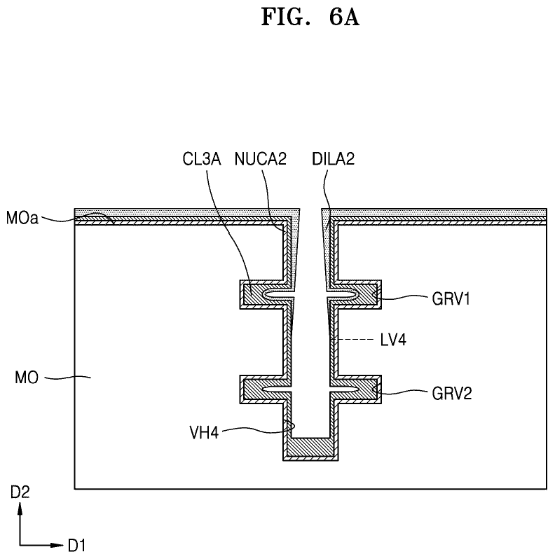

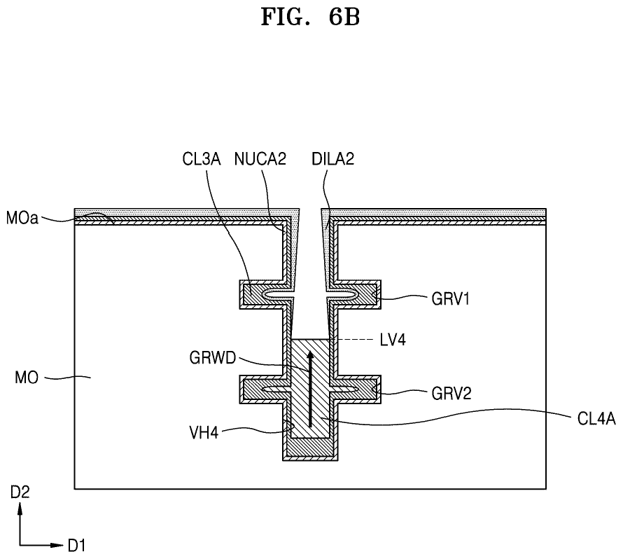

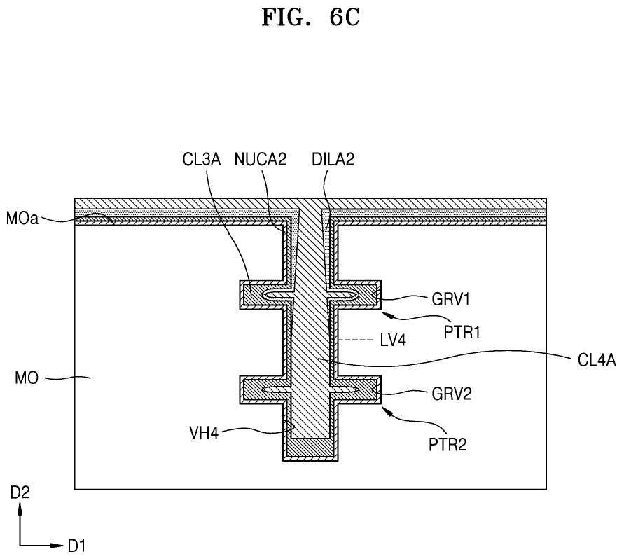

FIGS. 6A to 6C are cross-sectional views illustrating a method of manufacturing a semiconductor device, according to embodiments of the present inventive concept.

Referring to FIG. 6A, a mold structure MO may be provided. A description of the mold structure MO may be the same as the description of the mold structure MO of FIG. 4A.

A fourth via hole VH4 passing through at least a portion of the mold structure MO may be formed. An aspect ratio of the fourth via hole VH4 may be 30 or more, and a CD of the fourth via hole VH4 may be more than 0 kÅ and less than or equal to about 3 kÅ. The fourth via hole VH4 may be formed by an etching process. First and second grooves GRV1 and GRV2 that are recessed in a first direction D1 from the fourth via hole VH4 may be formed.

A second seed layer NUCA2 covering inner sidewalls of the first and second grooves GRV1 and GRV2 and the fourth via hole VH4 may be formed. The second seed layer NUCA2 may be formed on an entire surface of the mold structure MO. The second seed layer NUCA2 may extend up to an upper surface MOa of the mold structure MO from the inner sidewalls of the first and second grooves GRV1 and GRV2 and the fourth via hole VH4. For example, the second seed layer NUCA2 may be formed by a PVD process, a CVD process, an ALD process, a PEALD process, or a combination thereof. As another example, the second seed layer NUCA2 may be formed by using an electro-plating process. The second seed layer NUCA2 may include a material capable of being included in the first seed layer NUCA1 of FIG. 4A.

A third conductive layer CL3A may be formed on the second seed layer NUCA2. The third conductive layer CL3A may fill at least a portion of the fourth via hole VH4 and at least a portion of each of the first and second grooves GRV1 and GRV2. The third conductive layer CL3A may cover an exposed surface of the second seed layer NUCA2. For example, the third conductive layer CL3A may cover all of an exposed surface of the second seed layer NUCA2. The third conductive layer CL3A may be formed by a PVD process, a CVD process, an ALD process, a PEALD process, or a combination thereof. The third conductive layer CL3A may include a material capable of being included in the first conductive layer CL1A of FIG. 4A. For example, the third conductive layer CL3A may include the same material as that of the second seed layer NUCA2.

A second deposition inhibition layer DILA2 may be formed on the third conductive layer CL3A. The second deposition inhibition layer DILA2 may cover an uppermost surface of the third conductive layer CL3A. The second deposition inhibition layer DILA2 may cover the third conductive layer CL3A up to a fourth vertical level LV4, in the fourth via hole VH4 and the first groove GRV1. In the fourth via hole VH4 and the first groove GRV1, a horizontal width of the second deposition inhibition layer DILA2 may be progressively reduced as the second deposition inhibition layer DILA2 extends downward in a second direction D2 from the upper surface MOa of the mold structure MO.

The second deposition inhibition layer DILA2 may include a material capable of being included in the first deposition inhibition layer DILA1 of FIG. 4B. The second deposition inhibition layer DILA2 may include a material which is lower in SFE than that of the second seed layer NUCA2.

A method of forming the second deposition inhibition layer DILA2 may be the same as a method of forming the first deposition inhibition layer DILA1 of FIG. 4B. Therefore, in the fourth via hole VH4 and the first groove GRV1, a horizontal width of the second deposition inhibition layer DILA2 may be progressively reduced as the second deposition inhibition layer DILA2 extends downward in the second direction D2 from the upper surface MOa of the mold structure MO.

Referring to FIGS. 6B and 6C, a fourth conductive layer CL4A may be formed on the third conductive layer CL3A. The fourth conductive layer CL4A may grow in a growth direction GRWD from a bottom surface of the fourth via hole VH4. The growth direction GRWD may denote a direction in which the fourth conductive layer CL4A grows in the second direction D2 from the bottom surface of the fourth via hole VH4. The fourth conductive layer CL4A may grow in the growth direction GRWD from the bottom surface of the fourth via hole VH4 and may fill all of the other spaces of the first and second grooves GRV1 and GRV2 and the fourth via hole VH4 (e.g., remaining spaces of the first and second grooves GRV1 and GRV2 that are not filled by the seed layer NUCA2 and the third conductive layer CL3A). The fourth conductive layer CL4A may fill the other spaces of the first and second grooves GRV1 and GRV2, and thus, a first protrusion portion PTR1 and a second protrusion portion PTR2 may be formed. The fourth conductive layer CL4A may extend up to an uppermost surface of the second deposition inhibition layer DILA2. The principle of controlling the growth direction GRWD of the fourth conductive layer CL4A may be the same as the descriptions of the principle of controlling the growth direction GRWD of the second conductive layer CL2A given above with reference to FIGS. 4C and 4D.

Referring again to FIG. 5, a planarization process may be performed on the fourth conductive layer CL4A, the second deposition inhibition layer DILA2, the third conductive layer CL3A, and the second seed layer NUCA2. The planarization process may be performed so that the upper surface MOa of the mold structure MO is exposed. A seventh conductive pattern CL7 may be formed from the fourth conductive layer CL4A. A third deposition inhibition pattern DIL3 may be formed from the second deposition inhibition layer DILA2. A sixth conductive pattern CL6 may be formed from the third conductive layer CL3A. A fourth seed pattern NUC4 may be formed from the second seed layer NUCA2. Accordingly, a high aspect ratio via HARV3 may be formed.

For example, when a process of forming the third conductive layer CL3A is omitted, the second deposition inhibition layer DILA2 may be formed immediately after the second seed layer NUCA2 is formed. In this case, the fourth conductive layer CL4A might not fill the most of a space in the first groove GRV1 and the second groove GRV2. This may be because the first protrusion portion PTR1 and the second protrusion portion PTR2 respectively filling the first groove GRV1 and the second groove GRV2 include a void. As a result, when a process of forming the third conductive layer CL3A is omitted, the electrical characteristic and reliability of the semiconductor device 2 may degrade.

According to embodiments of the present inventive concept, in a case which forms the third high aspect ratio HARV3 including the first protrusion portion PTR1 and the second protrusion portion PTR2, the third conductive layer CL3A may be formed prior to the second deposition inhibition layer DILA2 and may fill at least a portion of each of the first groove GRV1 and the second groove GRV2. Subsequently, while growing the fourth conductive layer CL4A in the growth direction GRWD, the other spaces (e.g., remaining empty spaces) of the first and second grooves GRV1 and GRV2 and the fourth via hole VH4 may be filled with the fourth conductive layer CL4A. Accordingly, a void might not be formed in the first protrusion portion PTR1 and the second protrusion portion PTR2 of the third high aspect ratio HARV3. For this reason, the electrical characteristic and reliability of the semiconductor device 2 may be increased.

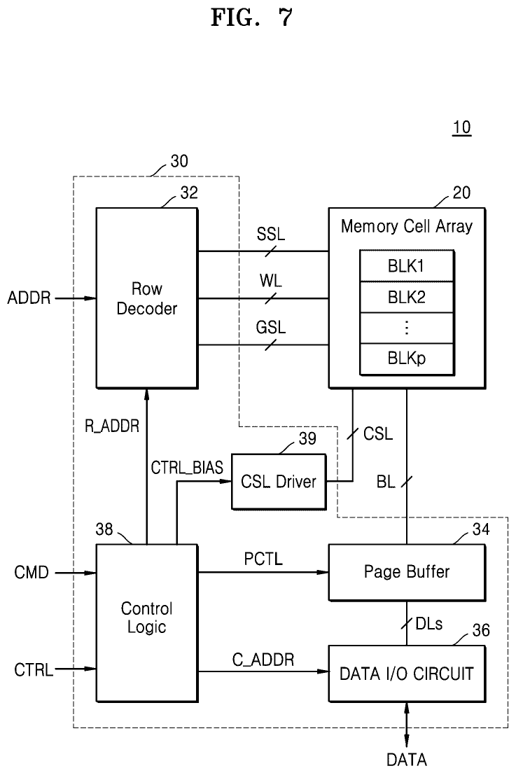

FIG. 7 is a block diagram of a semiconductor device 10 according to embodiments of the present inventive concept.

Referring to FIG. 7, the semiconductor device 10 may include a memory cell array 20 and a peripheral circuit 30. The memory cell array 20 may include a plurality of memory cell blocks BLK1, BLK2, . . . , and BLKp. Each of the plurality of memory cell blocks BLK1, BLK2, . . . , and BLKp may include a plurality of memory cells. The plurality of memory cell blocks BLK1, BLK2, . . . , and BLKp may be connected with the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, a control logic 38, and a common source line driver 39. The peripheral circuit 30 may further include various circuits such as a voltage generating circuit which generates various voltages that are used for an operation of the semiconductor device 10, an error correction circuit for correcting an error of data read from the memory cell array 20, and an I/O interface.

The memory cell array 20 may be connected with the row decoder 32 through the word line WL, the string selection line SSL, and the ground selection line GSL and may be connected with the page buffer 34 through the bit line BL. In the memory cell array 20, each of the memory cells included in each of the plurality of memory cell blocks BLK1, BLK2, . . . , and BLKp may be a flash memory cell. The memory cell array 20 may include a three-dimensional (3D) memory cell array. The 3D memory cell array may include a plurality of NAND strings, and each of the plurality of NAND strings may include a plurality of memory cells that are connected with a plurality of word lines WL, which are vertically stacked.

The peripheral circuit 30 may receive an address ADDR, a command CMD, and a control signal CTRL from the outside of the semiconductor device 10 and may transmit or receive data DATA to or from a device outside the semiconductor device 10.

In response to the address ADDR from the outside, the row decoder 32 may select at least one memory cell block from among the plurality of memory cell blocks BLK1, BLK2, . . . , and BLKp and may select a word line WL, a string selection line SSL, and a ground selection line GSL of the selected memory cell block. The row decoder 32 may transfer a voltage, which is for performing a memory operation, to the word line WL of the selected memory cell block.

The page buffer 34 may be connected with the memory cell array 20 through the bit line BL. In performing a program operation, the page buffer 34 may operate as a write driver to apply a voltage based on the data DATA, which is to be stored in the memory cell array 20, to the bit line BL, and in performing a read operation, the page buffer 34 may operate as a sensing amplifier to sense the data DATA stored in the memory cell array 20. The page buffer 34 may operate based on a control signal PCTL that is supplied from the control logic 38.

The data I/O circuit 36 may be connected with the page buffer 34 through a plurality of data lines DLs. In performing the program operation, the data I/O circuit 36 may receive the data DATA from a memory controller and may provide program data DATA to the page buffer 34, based on a column address C_ADDR that is provided from the control logic 38. In performing the read operation, the data I/O circuit 36 may provide the memory controller with read data DATA stored in the page buffer 34, based on the column address C_ADDR that is provided from the control logic 38.

The data I/O circuit 36 may transfer an input address or command to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data I/O circuit 36. The control logic 38 may generate various internal control signals that are used in the semiconductor device 10 in response to the control signal CTRL. For example, the control logic 38 may adjust a voltage level that is provided to the word line WL and the bit line BL in performing a memory operation such as the program operation or an erase operation.

The common source line driver 39 may be connected with the memory cell array 20 through the common source line CSL. The common source line driver 39 may apply a common source voltage (for example, a source voltage) or a ground voltage to the common source line CSL, based on a control signal CTRL_BIAS that is received from the control logic 38.

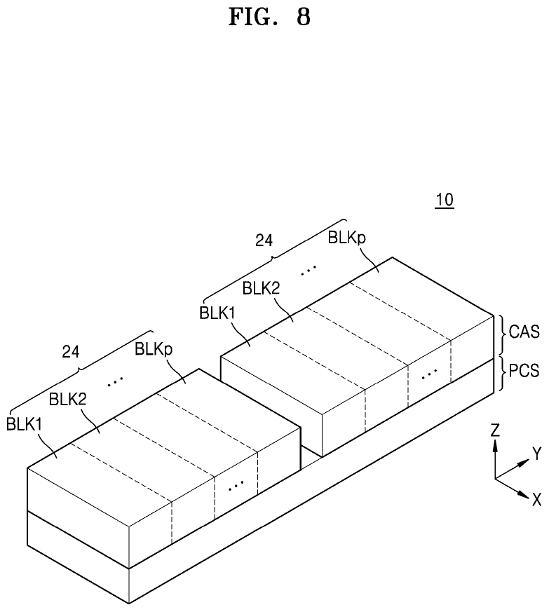

FIG. 8 is a schematic perspective view of a semiconductor device 10 according to embodiments of the present inventive concept.

Referring to FIG. 8, the semiconductor device 10 may include a cell array structure CAS and a peripheral circuit structure PCS, which overlap each other in a vertical direction Z. The cell array structure CAS may include the memory cell array 20 described above with reference to FIG. 7. The peripheral circuit structure PCS may include the peripheral circuit 30 described above with reference to FIG. 7.

The cell array structure CAS may include a plurality of tiles 24. Each of the plurality of tiles 24 may include a plurality of memory cell blocks BLK1, BLK2, . . . , and BLKp. Each of the plurality of memory cell blocks BLK1, BLK2, . . . , and BLKp may include a plurality of memory cells which are three-dimensionally arranged.

In embodiments of the present inventive concept, two tiles 24 may configure one mat, but are not limited thereto. The memory cell array 20 described above with reference to FIG. 7 may include a plurality of mats (for example, four mats), but the present inventive concept is not limited thereto.

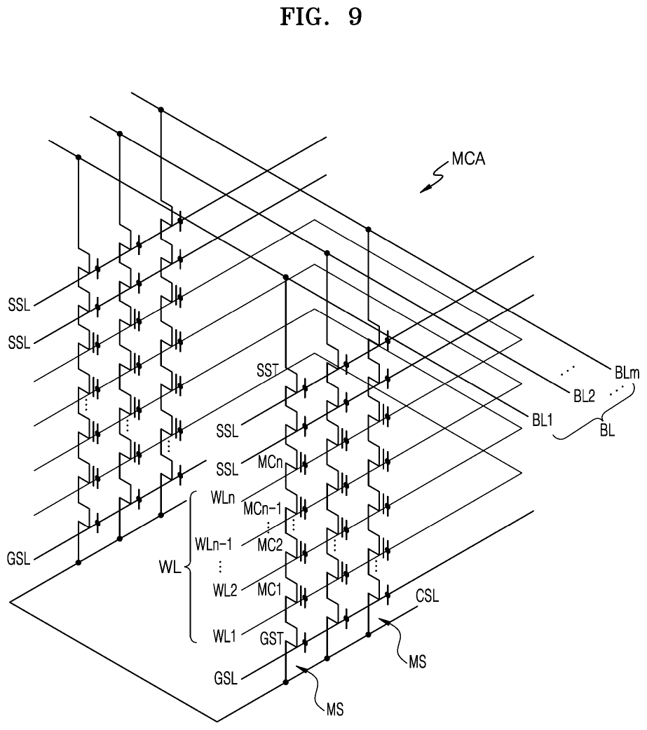

FIG. 9 is a circuit diagram of a memory cell array MCA of a semiconductor device according to embodiments of the present inventive concept. In FIG. 9, a circuit diagram of a vertical NAND flash memory device having a vertical channel structure is illustrated. Each of the plurality of memory cell blocks BLK1, BLK2, . . . , and BLKp illustrated in FIGS. 7 and 8 may include a memory cell array MCA having a circuit configuration illustrated in FIG. 9.

Referring to FIG. 9, the memory cell array MCA may include a plurality of memory cell strings MS. The memory cell array MCA may include a plurality of bit lines BL (BL1, BL2, . . . , and BLm), a plurality of word lines WL (WL1, WL2, . . . , WLn-1, and WLn), at least one string selection line SSL, at least one ground selection line GSL, and a common source line CSL. A plurality of memory cell strings MS may be formed between the plurality of bit lines BL and the plurality of common source lines CSL. In FIG. 9, a case is shown where each of the plurality of memory cell strings MS includes one ground selection line GSL and two string selection lines SSL, but the present inventive concept is not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn-1, and MCn. A drain region of the string selection transistor SST may be connected with the bit line BL, and a source region of the ground selection transistor GST may be connected with the common source line CSL. The common source line CSL may be a region which is connected with source regions of a plurality of ground selection transistors GST in common.

The string selection transistor SST may be connected with the string selection line SSL, and the ground selection transistor GST may be connected with the ground selection line GSL. Each of the plurality of memory cell transistors MC1, MC2, . . . , MCn-1, and MCn may be connected with the word line WL.

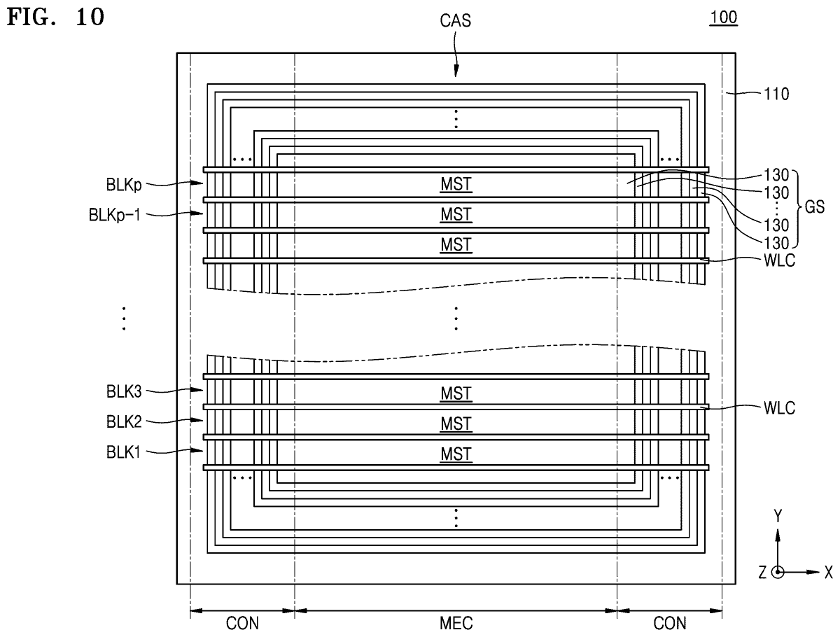

FIG. 10 is a schematic plan view of a partial region of a semiconductor device 100 according to embodiments of the present inventive concept.

Referring to FIG. 10, a cell array structure CAS of the semiconductor device 100 may include an upper substrate 110 and a plurality of memory cell blocks BLK1, BLK2, . . . , BLKp-1, and BLKp disposed on the upper substrate 110.

A peripheral circuit structure PCS (see FIG. 8) may be disposed under the upper substrate 110. The plurality of memory cell blocks BLK1, BLK2, . . . , BLKp-1, and BLKp may overlap the peripheral circuit structure PCS with the upper substrate 110 disposed therebetween in a vertical direction Z. The peripheral circuit structure PCS that is disposed under the upper substrate 110 may include the peripheral circuit 30 described above with reference to FIG. 7.

The cell array structure CAS may include a memory cell region MEC and a connection region CON that are disposed at both sides of the memory cell region MEC in a first horizontal direction X. Each of the plurality of memory cell blocks BLK1, BLK2, . . . , BLKp-1, and BLKp may include a memory stack structure MST extending in the first horizontal direction X all over the memory cell region MEC and the connection region CON. The memory stack structure MST may include a plurality of gate lines 130, which are stacked to overlap each other in a vertical direction Z, in the memory cell region MEC and the connection region CON on the upper substrate 110. In each of a plurality of memory stack structures MST, a plurality of gate lines 130 may configure a gate stack GS. In each of the plurality of memory stack structures MST, the plurality of gate lines 130 may configure a ground selection line GSL, a plurality of word lines WL, and a string selection line SSL each, of which are illustrated in FIG. 9. For example, an area of the plurality of gate lines 130 in an X-Y plane may progressively decrease as a distance from the upper substrate 110 increases. A center portion of each of the plurality of gate lines 130 overlapping each other in the vertical direction Z may configure the memory cell region MEC, and an edge portion of each of the plurality of gate lines 130 may configure the connection region CON.

A plurality of word line cut structures WLC extending long in the first horizontal direction X may be disposed in the memory cell region MEC and the connection region CON on the upper substrate 110. The plurality of word line cut structures WLC may be disposed while being spaced apart from one another in a second horizontal direction Y. Each of the plurality of memory cell blocks BLK1, BLK2, . . . , BLKp-1, and BLKp may be disposed between two adjacent word line cut structures WLC of the plurality of word line cut structures WLC.

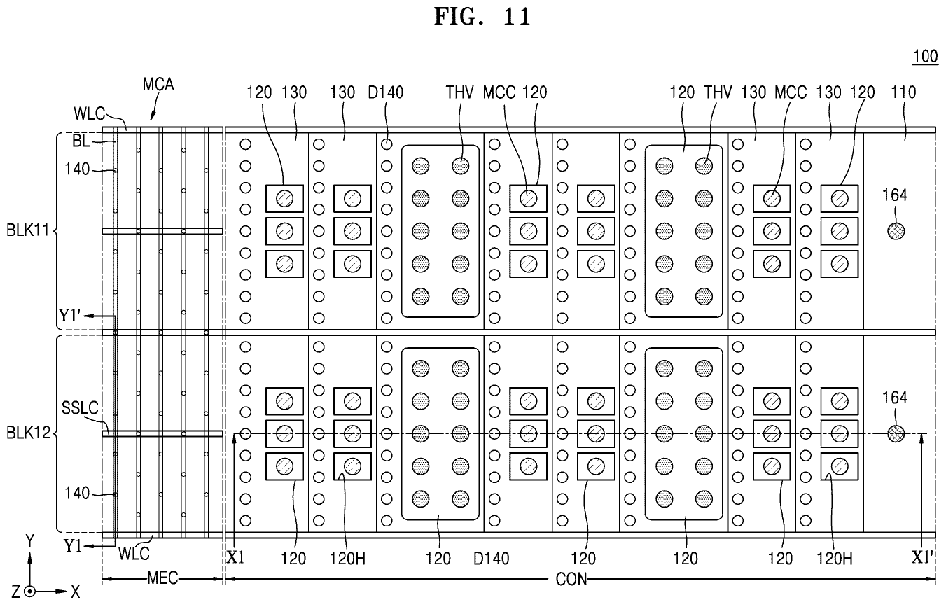

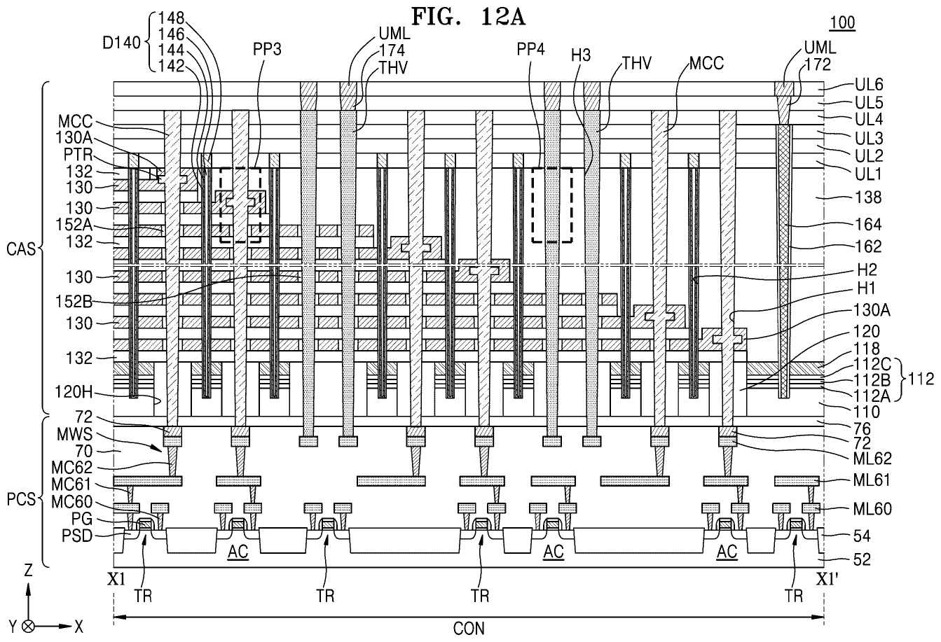

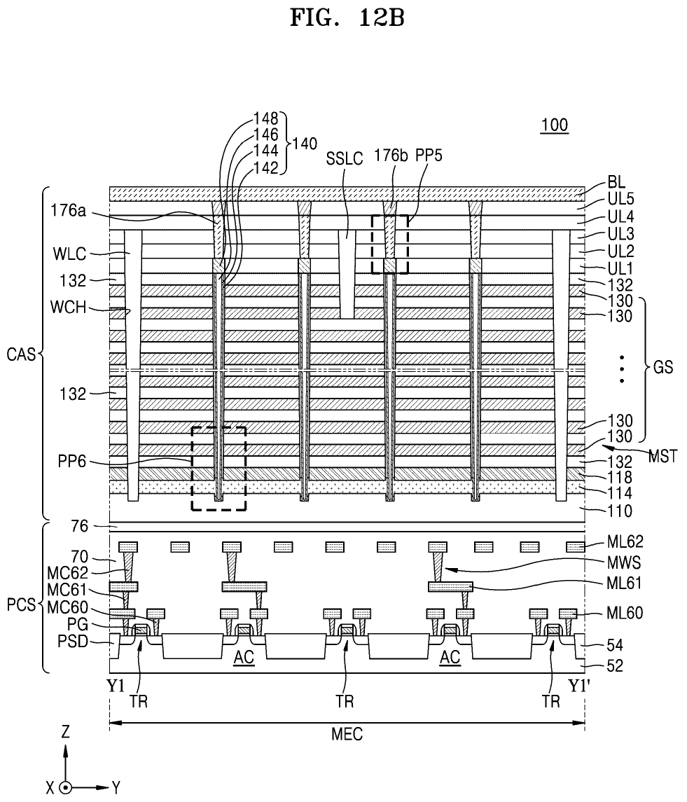

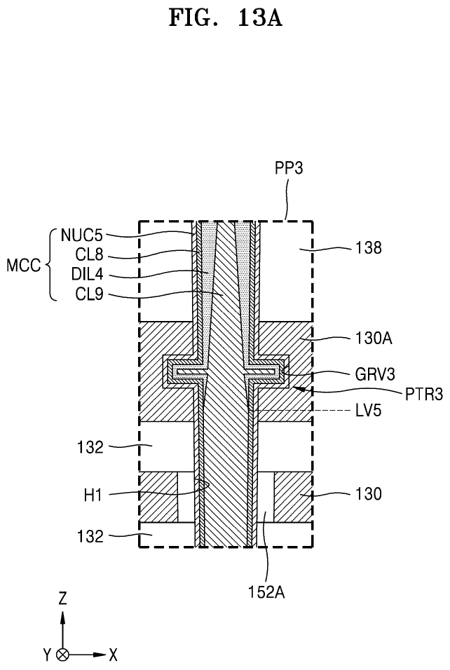

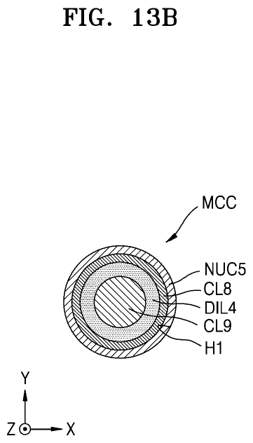

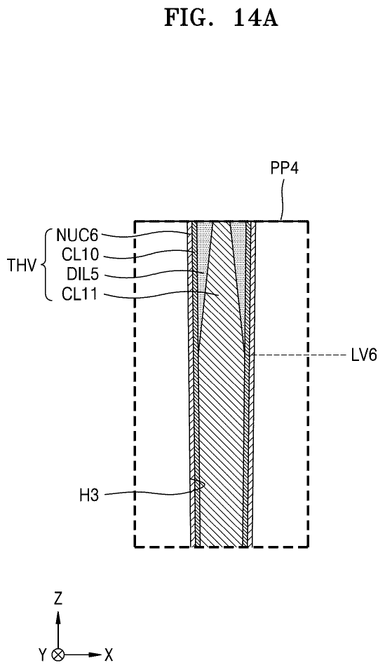

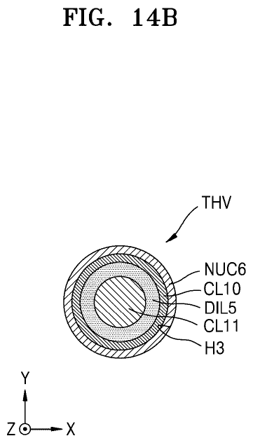

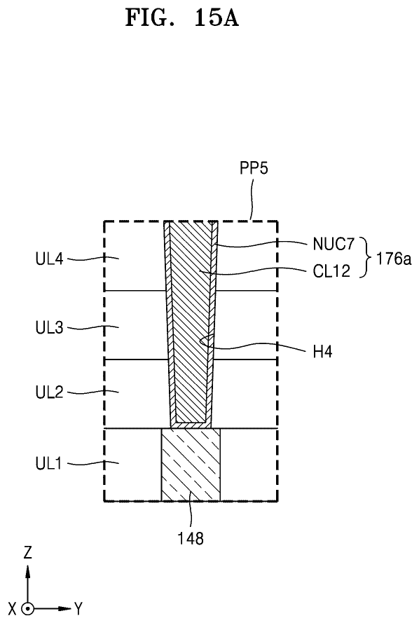

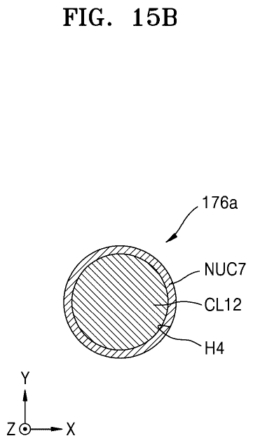

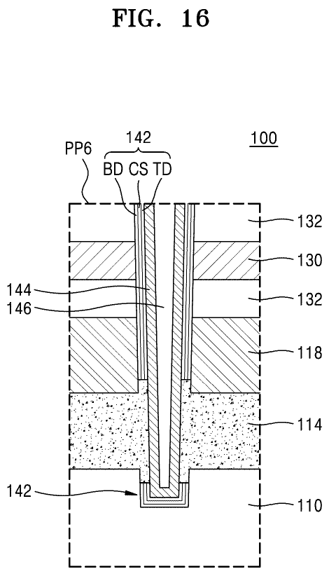

FIGS. 11 to 16 are cross-sectional views for describing in more detail a method of manufacturing a semiconductor device 100, according to embodiments of the present inventive concept. To provide a more detailed description, FIG. 11 is a schematic plan view of some elements of memory cell blocks BLK11 and BLK12, and FIG. 12A is a cross-sectional view taken along line X1-X1′ of FIG. 11. FIG. 12B is a cross-sectional view taken along line Y1-Y1′ of FIG. 11. FIG. 13A is an enlarged cross-sectional view of some elements included in a region PP3 of FIG. 12A. FIG. 13B is a plan view of an upper surface of a memory cell contact of FIG. 13A. FIG. 14A is an enlarged cross-sectional view of some elements included in a region PP4 of FIG. 12A. FIG. 14B is a plan view of an upper surface of a memory through via of FIG. 14A. FIG. 15A is an enlarged cross-sectional view of some elements included in a region PP5 of FIG. 12B. FIG. 15B is a plan view of an upper surface of a lower stud of FIG. 15A. FIG. 16 is an enlarged cross-sectional view of some elements included in a region PP6 of FIG. 12B. Memory cell blocks BLK11 and BLK12 illustrated in FIG. 11 may configure some of the plurality of memory cell blocks BLK1, BLK2, . . . , BLKp-1, and BLKp illustrated in FIG. 10.

Referring to FIGS. 11, 12A, and 12B, the semiconductor device 100 may include a peripheral circuit structure PCS and a cell array structure CAS which is disposed on the peripheral circuit structure PCS and overlaps the peripheral circuit structure PCS in a vertical direction Z.

The cell array structure CAS may include an upper substrate 110, a first conductive plate 114, a second conductive plate 118, an insulation plate 112, and a memory stack structure MST. As illustrated in FIG. 12A, the insulation plate 112, the second conductive plate 118, and the memory stack structure MST may be disposed on the upper substrate 110 in a connection region CON of the cell array structure CAS. For example, the insulation plate 112, the second conductive plate 118, and the memory stack structure MST may be sequentially stacked on the upper substrate 110 in a connection region CON of the cell array structure CAS. As illustrated in FIG. 12B, the first conductive plate 114, the second conductive plate 118, and the memory stack structure MST may be sequentially stacked on the upper substrate 110 in a memory cell region MEC of the cell array structure CAS.

The first conductive plate 114 and the second conductive plate 118 may perform a function of the common source line CSL described above with reference to FIG. 9. The first conductive plate 114 and the second conductive plate 118 may function as a source region which supplies a current to vertical memory cells included in the cell array structure CAS.

In embodiments of the present inventive concept, the upper substrate 110 may include a semiconductor material such as polysilicon. For example, each of the first conductive plate 114 and the second conductive plate 118 may include a doped polysilicon layer, a metal layer, or a combination thereof. For example, the metal layer may include tungsten (W), but is not limited thereto. The memory stack structure MST may include a gate stack GS. The gate stack GS may include a plurality of gate lines 130 which extend in parallel in a horizontal direction and overlap each other in the vertical direction Z. For example, each of the plurality of gate lines 130 may include metal, metal silicide, an impurity-doped semiconductor, or a combination thereof. For example, each of the plurality of gate lines 130 may include metal such as tungsten, nickel, cobalt, or tantalum, metal silicide such as tungsten silicide, nickel silicide, cobalt silicide, or tantalum silicide, doped polysilicon, or a combination thereof.

An insulation layer 132 may be disposed between the second conductive plate 118 and the plurality of gate lines 130 and between two adjacent gate lines 130 of the plurality of gate lines 130. A gate line 130 of an uppermost layer of the plurality of gate lines 130 may be covered by the insulation layer 132. For example, the insulation layer 132 may include silicon oxide.

A plurality of word line cut structures WLC may extend lengthwise in a first horizontal direction X on the upper substrate 110, in the memory cell region MEC and the connection region CON. A width of each of a plurality of gate lines 130, included in the memory cell blocks BLK11 and BLK12, in a second horizontal direction Y may be defined by the plurality of word line cut structures WLC.

Each of the plurality of word line cut structures WLC may include an insulation structure. In embodiments of the present inventive concept, the insulation structure may include silicon oxide, silicon nitride, silicon oxynitride, or a low-k dielectric material. For example, the insulation structure may include a silicon oxide layer, a silicon nitride layer, a SiON layer, a SiOCN layer, a SiCN layer, or a combination thereof. In embodiments of the present inventive concept, at least a portion of the insulation structure may include an air gap. The term “air” used herein may denote air or other gases which may occur in a manufacturing process.

A plurality of gate lines 130 configuring one gate stack GS may be stacked to overlap each other on the second conductive plate 118 in a vertical direction Z, between two adjacent word line cut structures WLC in the second horizontal direction. In each of the plurality of gate lines 130 configuring one gate stack GS may include the ground selection line GSL, the plurality of word lines WL, and the string selection line SSL each of which are described above with reference to FIG. 9.

As illustrated in FIG. 12B, in a plurality of gate lines 130, two upper gate lines 130 may be spaced apart from each other in the second horizontal direction Y with a string selection line cut structure SSLC disposed therebetween. Two gate lines 130, which are spaced apart from each other with the string selection line cut structure SSLC disposed therebetween, may configure the string selection line SSL that is described above with reference to FIG. 9. In FIG. 12B, a case where one string selection line cut structure SSLC is formed in one gate stack GS is illustrated, but the present inventive concept is not limited to the illustration of FIG. 12B. For example, at least two string selection line cut structures SSLC may be formed in one gate stack GS. The string selection line cut structure SSLC may include an insulation layer. In embodiments of the present inventive concept, the string selection line cut structure SSLC may include an oxide layer, a nitride layer, or an insulation layer configured by a combination thereof. In embodiments of the present inventive concept, at least a portion of the string selection line cut structure SSLC may be configured with an air gap.

As illustrated in FIGS. 11 and 12B, in the memory cell region MEC, a plurality of channel structures 140 may pass through the plurality of gate lines 130, the plurality of insulation layers 132, the second conductive plate 118, and the first conductive plate 114 and may extend in the vertical direction Z, on the upper substrate 110. The plurality of channel structures 140 may be arranged spaced apart from one another by a certain interval in the first horizontal direction X and the second horizontal direction Y. Each of the plurality of channel structures 140 may include a gate dielectric layer 142, a channel region 144, a buried insulation layer 146, and a drain region 148.

As illustrated in FIG. 16, the gate dielectric layer 142 may include a tunneling dielectric layer TD, a charge storage layer CS, and a blocking dielectric layer BD, which are sequentially stacked on a sidewall of the channel region 144. A relative thickness of each of the tunneling dielectric layer TD, the charge storage layer CS, and the blocking dielectric layer BD is not limited to the illustration of FIG. 16 and may be variously changed.

The tunneling dielectric layer TD may include, for example, silicon oxide, hafnium oxide, aluminum oxide, zirconium oxide, or tantalum oxide. The charge storage layer CS may be a region which may store electrons passing through the tunneling dielectric layer TD from the channel region 144 and may include silicon nitride, boron nitride, silicon boron nitride, or impurity-doped polysilicon. The blocking dielectric layer BD may include, for example, silicon oxide, silicon nitride, or metal oxide which is greater in dielectric constant than silicon oxide. The metal oxide may include hafnium oxide, aluminum oxide, zirconium oxide, tantalum oxide, or a combination thereof.

As illustrated in FIG. 16, the first conductive plate 114 may pass through a partial region of the gate dielectric layer 142 in a horizontal direction (e.g., an X direction and/or a Y direction) and may contact the channel region 144. A thickness (or a Z-direction size) of a portion, overlapping the gate dielectric layer 142, of the first conductive plate 114 may be greater than a thickness (or a Z-direction size) of a portion, vertically overlapping the second conductive plate 118, of the first conductive plate 114. The gate dielectric layer 142 may include a portion, covering a sidewall of the channel region 144 at a level which is higher than the level at which the first conductive plate 114 is disposed, and a portion covering a lower surface of the channel region 144 at a level which is lower than the level at which the first conductive plate 114 is disposed. The channel region 144 may be spaced apart from the upper substrate 110 with a lowermost portion of the gate dielectric layer 142 disposed therebetween. A sidewall of the channel region 144 may contact the first conductive plate 114 and may be configured to be electrically connected with the first conductive plate 114.

As illustrated in FIGS. 12B and 16, the channel region 144 may have a cylindrical shape. The channel region 144 may include doped polysilicon or undoped polysilicon.

The buried insulation layer 146 may fill an internal space of the channel region 144. The buried insulation layer 146 may include an insulating material. For example, the buried insulation layer 146 may include silicon oxide, silicon nitride, silicon oxynitride, or a combination thereof. In embodiments of the present inventive concept, the buried insulation layer 146 may be omitted. In this case, the channel region 144 may have a pillar structure or cylindrical shape where there is no internal space.

The drain region 148 may include a doped polysilicon layer. A plurality of drain regions 148 may be insulated from one another by a first upper insulation layer UL1. In the memory cell region MEC, the plurality of channel structures 140 and the first upper insulation layer UL1 may be covered by a second upper insulation layer UL2.

The string selection line cut structure SSLC may pass through the first upper insulation layer UL1 and the second upper insulation layer UL2 in the vertical direction Z. An upper surface of the string selection line cut structure SSLC, an upper surface of the word line cut structure WLC, and an upper surface of the second upper insulation layer UL2 may be substantially coplanar with each other. A third upper insulation layer UL3, a fourth upper insulation layer UL4, and a fifth upper insulation layer UL5 may be sequentially formed on the string selection line cut structure SSLC, the word line cut structure WLC, and the second upper insulation layer UL2. Each of the first upper insulation layer UL1, the second upper insulation layer UL2, the third upper insulation layer UL3, the fourth upper insulation layer UL4, and the fifth upper insulation layer UL5 may include, for example, oxide, nitride, or a combination thereof.

As illustrated in FIGS. 11 and 12B, in the memory cell region MEC of the memory stack structure MST, a plurality of bit lines BL may be disposed on the fifth upper insulation layer UL5. The plurality of bit lines BL may extend in parallel with each other in the second horizontal direction Y. Each of the plurality of channel structures 140 may be connected with a plurality of contact plugs 176b, which pass through the fifth upper insulation layer UL5, through a plurality of studs 176a, which pass through the second upper insulation layer UL2, the third upper insulation layer UL3, and the fourth upper insulation layer UL4. The plurality of contact plugs 176b may be respectively connected with the plurality of bit lines BL. Therefore, the plurality of channel structures 140 may be respectively connected with the plurality of bit lines BL.

As illustrated in FIG. 12A, the insulation plate 112 and the second conductive plate 118 may be sequentially stacked on the upper substrate 110, in the connection region CON of the memory stack structure MST. The insulation plate 112 may include an insulation layer having a multi-layer structure including a first insulation layer 112A, a second insulation layer 112B, and a third insulation layer 112C which are sequentially stacked on the upper substrate 110. In embodiments of the present inventive concept, the first insulation layer 112A and the third insulation layer 112C may each include silicon oxide, and the second insulation layer 112B may include silicon nitride.

In the connection region CON, each of the plurality of gate lines 130 may include a gate pad portion 130A which has a thickness in the vertical direction Z that is greater than another portion of a corresponding gate line 130. The gate pad portion 130A of the gate line 130 may be disposed at an edge portion of the gate line 130. For example, the edge portion, at which the gate pad portion 130a is positioned, is the farthest position away from the memory cell region MEC of the gate line 130. Only the gate pad portion 130A included in one end portion of each of some gate lines 130 among the plurality of gate lines 130 is illustrated in FIG. 12A, but a gate line 130 where a gate pad portion 130A is not seen in FIG. 12A may include a gate pad portion 130A that is provided at the other portion which is not seen in FIG. 12A.

In the connection region CON, an edge portion of each of the plurality of insulation layers 132 and the plurality of gate lines 130 may be covered by an interlayer insulation layer 138. The interlayer insulation layer 138 may include, for example, silicon oxide, but the present inventive concept is not limited thereto.

As illustrated in FIGS. 11 and 12A, a plurality of memory cell contacts MCC may be disposed in the connection region CON. Each of the plurality of memory cell contacts MCC may pass through at least a portion of a corresponding layer of the interlayer insulation layer 138, the plurality of gate lines 130, and the plurality of insulation layers 132. Each of the plurality of memory cell contacts MCC may be disposed in a first hole HI passing through at least one of the plurality of gate lines 130. Each of the plurality of memory cell contacts MCC may pass through at least one gate line 130, at least one insulation layer 132, the second conductive plate 118, the insulation plate 112, and the upper substrate 110, and may extend in the vertical direction Z up to the peripheral circuit structure PCS.

Each of the plurality of memory cell contacts MCC may be connected with one gate line 130 that is selected from among the plurality of gate lines 130 and might not be connected with the other gate line 130 except the selected one gate line 130. Each of the plurality of memory cell contacts MCC may contact a gate pad portion 130A of one gate line 130 selected from among the plurality of gate lines 130 and may be connected with the selected one gate line 130 through the gate pad portion 130A. In the first hole H1, the memory cell contact MCC may be spaced apart from the other gate line 130 except the selected one gate line 130 in a horizontal direction. A first insulation ring 152A may be disposed between the memory cell contact MCC and a gate line 130 which is not connected with the memory cell contact MCC. In embodiments of the present inventive concept, the first insulation ring 152A may include silicon oxide, but the present inventive concept is not limited thereto.

Referring to FIGS. 12A and 13A, the memory cell contact MCC may be disposed in the first hole H1 and a third groove GRV3 which is recessed in the first horizontal direction X or the second horizontal direction Y from the first hole H1. From a plan view, the third groove GRV3 may have, for example, a polygonal, circular, or oval annual shape. The memory cell contact MCC may include a third protrusion portion PTR3 which protrudes into the third groove GRV3. The third protrusion portion PTR3 may be disposed at a vertical level with respect to the gate pad portion 130A that contacts the memory cell contact MCC. The third protrusion portion PTR3 may contact the gate pad portion 130A. For example, the third protrusion portion PTR3 may be disposed in the gate pad portion 130A.

The memory cell contact MCC may include a third seed pattern NUC5, an eighth conductive pattern CL8, a fourth deposition inhibition pattern DIL4, and a ninth conductive pattern CL9.

The fifth seed pattern NUC5 may cover inner sidewalls of the first hole H1 and the third groove GRV3. The eighth conductive pattern CL8 may be disposed on the fifth seed pattern NUC5. The eighth conductive pattern CL8 may fill at least a portion of the first hole H1 and at least a portion of the third groove GRV3. The fourth deposition inhibition pattern DIL4 may cover a portion of an inner sidewall of the eighth conductive pattern CL8, on the memory cell contact MCC. The ninth conductive pattern CL9 may fill the other portions of the first hole H1 and the third groove GRV3, which are not filled with the third seed pattern NUC5, the eighth conductive pattern CL8, and the fourth deposition inhibition pattern DIL4.

The fourth deposition inhibition pattern DIL4 may have a tapered shape where a horizontal width of the fourth deposition inhibition pattern DIL4 is progressively reduced as the fourth deposition inhibition pattern DIL4 extends downward in the vertical direction Z. The fourth deposition inhibition pattern DIL4 may extend downward in the vertical direction Z up to a fifth vertical level LV5 from an upper surface of the memory cell contact MCC. The fifth vertical level LV5 may be disposed between an upper surface and a lower surface of the memory cell contact MCC. For example, the fifth vertical level LV5 may be a predetermined vertical level in the memory cell contact MCC. The fourth vertical level LV4 may be higher or lower than a vertical level of the third groove GRV3. When the fourth vertical level LV4 is lower than the vertical level of the third groove GRV3, the fourth deposition inhibition pattern DIL4 may include a portion which extends in a horizontal direction toward the third groove GRV3. In the extended portion, a horizontal width of the fourth deposition inhibition pattern DIL4 may denote a thickness of the extended portion in a direction perpendicular to the normal line at an arbitrary point of the extended portion.

The ninth conductive pattern CL9 may be disposed on the fourth deposition inhibition pattern DIL4 and the eighth conductive pattern CL8. The fourth deposition inhibition pattern DIL4 may be disposed between the eighth conductive pattern CL8 and the ninth conductive pattern CL9, between the fourth vertical level LV4 and an upper surface of the memory cell contact MCC. The eighth conductive pattern CL8 and the ninth conductive pattern CL9 may be spaced apart from each other with the fourth deposition inhibition pattern DIL4 disposed therebetween, between the fourth vertical level LV4 and the upper surface of the memory cell contact MCC. The fifth seed pattern NUC5 and the ninth conductive pattern CL9 may be spaced apart from each other with the eighth conductive pattern CL8 and the fourth deposition inhibition pattern DIL4 disposed therebetween, between the fourth vertical level LV4 and the upper surface of the memory cell contact MCC. The eighth conductive pattern CL8 may contact the ninth conductive pattern CL9, between the fourth vertical level LV4 and a lower surface of the memory cell contact MCC. The eighth conductive pattern CL8 may be disposed between the fifth seed pattern NUC5 and the ninth conductive pattern CL9, between the fourth vertical level LV4 and the lower surface of the memory cell contact MCC. For example, the fourth deposition inhabitation pattern DIL4 is not disposed the fifth seed pattern NUC5 and the ninth conductive pattern CL9, between the fourth vertical level LV4 and the lower surface of the memory cell contact MCC. The fourth deposition inhibition pattern DIL4 may be formed up to only the fourth vertical level LV4 from the upper surface of the memory cell contact MCC.

The memory cell contact MCC may have a high aspect ratio. An aspect ratio of the memory cell contact MCC may be 30 or more, and a CD of the memory cell contact MCC may be more than 0 kÅ and less than or equal to about 3 kÅ. The CD of the memory cell contact MCC may denote a width of the upper surface of the memory cell contact MCC in the first horizontal direction X or the second horizontal direction Y. Because the memory cell contact MCC has a high aspect ratio and includes the third protrusion portion PTR3, the memory cell contact MCC may be an element corresponding to the third high aspect ratio via HARV3 of FIG. 5. Accordingly, an effect of the third high aspect ratio via HARV3 described above with reference to FIGS. 5 to 6C may also be applied to the memory cell contact MCC.

The fifth seed pattern NUC5 may include a material capable of being included in the first seed pattern NUC1 of FIG. 1. The eighth conductive pattern CL8 may include a material capable of being included in the first conductive pattern CL1 of FIG. 1. For example, the eighth conductive pattern CL8 may include the same material as that of the fifth seed pattern NUC5. The fourth deposition inhibition pattern DIL4 may include a material capable of being included in the first deposition inhibition pattern DIL1 of FIG. 1. The ninth conductive pattern CL9 may include a material capable of being included in the first conductive pattern CL1 of FIG. 1. For example, the ninth conductive pattern CL9 may include the same material as that of the eighth conductive pattern CL8.

Referring to FIG. 13B, from a plan view, the fourth deposition inhibition pattern DIL4 may have an annular shape and may surround the ninth conductive pattern CL9. The eighth conductive pattern CL8 may have an annular shape and may surround the fourth deposition inhibition pattern DIL4, and the fifth seed pattern NUC5 may have an annular shape and may surround the eighth conductive pattern CL8.

As illustrated in FIGS. 11 and 12A, a plurality of dummy channel structures D140 may be disposed in the connection region CON. Each of the plurality of dummy channel structures D140 may pass through at least a portion of a corresponding layer of the interlayer insulation layer 138, the plurality of gate lines 130, and the plurality of insulation layers 132. Each of the plurality of dummy channel structures D140 may be disposed in a second hole H2 that passes through at least one of the plurality of gate lines 130. Each of the plurality of dummy channel structures D140 may pass through at least one gate line 130, at least one insulation layer 132, the second conductive plate 118, and the insulation plate 112, and may be inserted into the upper substrate 110.

The plurality of dummy channel structures D140 may be arranged apart from one another by a certain interval in the first horizontal direction X and the second horizontal direction Y. Each of the plurality of dummy channel structures D140, like the channel structure 140, may include a gate dielectric layer 142, a channel region 144, a buried insulation layer 146, and a drain region 148. The number and arrangement shape of dummy channel structures D140 illustrated in FIG. 11 may be merely an embodiment, and the present inventive concept is not limited thereto. In the connection region CON, the plurality of dummy channel structures D140 may be variously arranged at various positions selected in the memory cell structure MST.

In the connection region CON, the interlayer insulation layer 138 may be covered by the first upper insulation layer UL1. The drain regions 148 of the plurality of dummy channel structures D140 may be insulated from each other by the first upper insulation layer UL1. In the connection region CON, the plurality of dummy channel structures D140 and the first upper insulation layer UL1 may be covered by the second upper insulation layer UL2.

As illustrated in FIGS. 11 and 12A, a plurality of through vias THV may be disposed in the connection region CON. Each of the plurality of through vias THV may pass through at least a portion of a corresponding layer of the interlayer insulation layer 138, the plurality of gate lines 130, and the plurality of insulation layers 132. Each of the plurality of through vias THV may be disposed in a third hole H3 that passes through at least one of the plurality of gate lines 130. Each of the plurality of through vias THV may pass through at least one gate line 130, at least one insulation layer 132, the second conductive plate 118, the insulation plate 112, and the upper substrate 110, and may extend in the vertical direction Z up to the peripheral circuit structure PCS. In the third hole H3, the through via THV might not be connected with any portion of each of the plurality of gate lines 130. In the third hole H3, the through via THV may be spaced apart from all of the plurality of gate lines 130. In the third hole H3, a second insulation ring 152B may be disposed between the gate line 130 and the through via THV. In embodiments of the present inventive concept, the second insulation ring 152B may include silicon oxide, but the present inventive concept is not limited thereto. The plurality of through vias THV may be connected with a peripheral circuit that is included in the peripheral circuit structure PCS.

Referring to FIGS. 12A and 14A, the through via THV may be disposed in the third hole H3 that passes through at least one of the plurality of gate lines 130. The through via THV may include a sixth seed pattern NUC6, a tenth conductive pattern CL10, a fifth deposition inhibition pattern DIL5, and an eleventh conductive pattern CL11.

The sixth seed pattern NUC6 may cover an inner sidewall of the third hole H3. The tenth conductive pattern CL10 may be disposed on the sixth seed pattern NUC6. The fifth deposition inhibition pattern DIL5 may cover a portion of an inner sidewall of the tenth conductive pattern CL10, in the third hole H3.

The fifth deposition inhibition pattern DIL5 may have a tapered shape where a horizontal width of the fifth deposition inhibition pattern DIL5 is progressively reduced as the fifth deposition inhabitation pattern DIL5 extends downward in the vertical direction Z. The horizontal width of the fifth deposition inhibition pattern DIL5 may denote a width in the first horizontal direction X or the second horizontal direction Y. The fifth deposition inhibition pattern DIL5 may extend downward in the vertical direction Z up to a sixth vertical level LV6 from an upper surface of the through via THV. The sixth vertical level LV6 may be disposed between an upper surface and a lower surface of the through via THV. The sixth vertical level LV6 may be a predetermined vertical level in the through via THV. A vertical level may denote a vertical distance downward in the vertical direction Z from the upper surface of the through via THV.

The eleventh conductive pattern CL11 may be disposed on the fifth deposition inhibition pattern DIL5 and the tenth conductive pattern CL10. The fifth deposition inhibition pattern DIL5 may be disposed between the tenth conductive pattern CL10 and the eleventh conductive pattern CL11, between the sixth vertical level LV6 and an upper surface of the through via THV. The tenth conductive pattern CL10 and the eleventh conductive pattern CL11 may be spaced apart from each other with the fifth deposition inhibition pattern DIL5 disposed therebetween, between the sixth vertical level LV6 and the upper surface of the through via THV. The sixth seed pattern NUC6 and the eleventh conductive pattern CL11 may be spaced apart from each other with the tenth conductive pattern CL10 and the fifth deposition inhibition pattern DIL5 disposed therebetween, between the sixth vertical level LV6 and the upper surface of the through via THV. The tenth conductive pattern CL10 may contact the eleventh conductive pattern CL11, between the sixth vertical level LV6 and a lower surface of the through via THV. The tenth conductive pattern CL10 may be disposed between the sixth seed pattern NUC6 and the eleventh conductive pattern CL11, between the sixth vertical level LV6 and the lower surface of the through via THV. For example, the fifth deposition inhabitation pattern DIL5 is not disposed the sixth seed pattern NUC6 and the eleventh conductive pattern CL11, between the sixth vertical level LV6 and the lower surface of the through via THV. The fifth deposition inhibition pattern DIL5 may be formed up to only the sixth vertical level LV6 from the upper surface of the through via THV.

The sixth seed pattern NUC6 may include a material capable of being included in the first seed pattern NUC1 of FIG. 1. For example, the sixth seed pattern NUC6 may include the same material as that of the fifth seed pattern NUC5. The tenth conductive pattern CL10 may include a material capable of being included in the first conductive pattern CL1 of FIG. 1. For example, the tenth conductive pattern CL10 may include the same material as that of the sixth seed pattern NUC6. For example, the tenth conductive pattern CL10 may include the same material as that of the eighth conductive pattern CL8 of FIG. 13A. The fourth deposition inhibition pattern DIL4 may include a material capable of being included in the first deposition inhibition pattern DIL1 of FIG. 1. For example, the fourth deposition inhibition pattern DIL4 may include the same material as that of the third deposition inhibition pattern DIL3 of FIG. 12A. The eleventh conductive pattern CL11 may include a material capable of being included in the first conductive pattern CL1 of FIG. 1. For example, the eleventh conductive pattern CL11 may include the same material as that of the tenth conductive pattern CL10.

Referring to FIG. 14B, from a plan view, the fifth deposition inhibition pattern DIL5 may have an annular shape and may surround the eleventh conductive pattern CL11. The tenth conductive pattern CL10 may have an annular shape and may surround the fifth deposition inhibition pattern DIL5, and the sixth seed pattern NUC6 may have an annular shape and may surround the tenth conductive pattern CL10.

Referring to FIG. 15A, a stud 176a may be disposed in a fourth hole H4 that passes through the second upper insulation layer UL2, the third upper insulation layer UL3, and the fourth upper insulation layer UL4. The stud 176a may include a seventh seed pattern NUC7, which covers an inner sidewall of the fourth hole H4, and a twelfth conductive pattern CL12 that is disposed on the seventh seed pattern NUC7. The seventh seed pattern NUC7 may surround a sidewall and a lower surface of the twelfth conductive pattern CL12. The seventh seed pattern NUC7 may expose an upper surface of the twelfth conductive pattern CL12. The twelfth conductive pattern CL12 may fill all of the other space of the fourth via hole VH4 except a space where the seventh seed pattern NUC7 is disposed.

The stud 176a may have a low aspect ratio. An aspect ratio of the stud 176a may be more than 0 and 5 or less, and a CD of the stud 176a may be more than 0 kÅ and less than or equal to about 1 kÅ. The CD of the stud 176a may denote a width of an upper surface of the stud 176a in the first horizontal direction X or the second horizontal direction Y. Because the stud 176a has a low aspect ratio, the stud 176a may be an element corresponding to the low aspect ratio via of FIG. 1.

The seventh seed pattern NUC7 may include a material capable of being included in the first seed pattern NUC1 of FIG. 1. For example, the seventh seed pattern NUC7 may include the same material as that of the fifth seed pattern NUC5 of FIG. 13A or/and the sixth seed pattern NUC6 of FIG. 14A. The twelfth conductive pattern CL12 may include a material capable of being included in the first conductive pattern CL1 of FIG. 1. For example, the twelfth conductive pattern CL12 may include the same material as that of the eighth conductive pattern CL8 of FIG. 13A or/and the tenth conductive pattern CL10 of FIG. 14A.

Referring to FIG. 15B, from a plan view, the seventh seed pattern NUC7 of the stud 176a may have an annular shape and may surround the twelfth conductive pattern CL12.

Referring to FIGS. 12A and 12B, upper surfaces of the memory cell contact MCC, the through via THV, and the stud 176a may be substantially coplanar. Therefore, all of the fifth to seventh seed patterns NUC5 to NUC7, the eighth to twelfth conductive patterns CL8 to CL12, and the fourth and fifth deposition inhibition patterns DIL4 and DIL5 each illustrated in FIGS. 13A to 15B may be substantially coplanar.

As illustrated in FIGS. 11 and 12A, a conductive plate contact 164 may be disposed in the connection region CON. The conductive plate contact 164 may pass through the third upper insulation layer UL3, the second upper insulation layer UL2, the first upper insulation layer UL1, the interlayer insulation layer 138, the second conductive plate 118, and the insulation plate 112, and may extend in the vertical direction Z up to the upper substrate 110. A sidewall of the conductive plate contact 164 may be covered by the insulation spacer 162. The fourth upper insulation layer UL4 may cover an upper surface of each of the conductive plate contact 164 and the insulation spacer 162.

A plurality of memory cell contacts MCC and a plurality of through vias THV may pass through the second upper insulation layer UL2, the third upper insulation layer UL3, and the fourth upper insulation layer UL4. An upper surface of each of the plurality of memory cell contacts MCC may be covered by the fifth upper insulation layer UL5 and the sixth upper insulation layer UL6. Each of the plurality of through vias THV may be connected with one upper wiring layer UML of a plurality of upper wiring layers UML through one contact plug 174 of the plurality of contact plugs 174 that pass through the fifth upper insulation layer UL5.

The conductive plate contact 164 may be connected with one upper wiring layer UML of the plurality of upper wiring layers UML through the contact plug 172 that passes through the fourth upper insulation layer UL4 and the fifth upper insulation layer UL5.

The plurality of upper wiring layers UML may be disposed at the same vertical level as a plurality of bit lines BL that are disposed in the memory cell region MEC. A region between a corresponding upper wiring layer UML of the plurality of upper wiring layers UML and a corresponding bit line BL of the plurality of bit lines BL may be filled with the sixth upper insulation layer UL6. The sixth upper insulation layer UL6 may include, for example, oxide, nitride, or a combination thereof.

The plurality of memory cell contacts MCC, the plurality of through vias THV, the conductive plate contact 164, the plurality of contact plugs 172 and 174, and the plurality of upper wiring layer UML may each include, for example, W, Ti, Ta, Cu, Al, titanium nitride, tantalum nitride, tungsten nitride, or a combination thereof.

As illustrated in FIGS. 12A and 12B, the peripheral circuit structure PCS may include a lower substrate 52, a plurality of peripheral circuits formed on the lower substrate 52, and a multi-layer wiring structure MWS which connects the plurality of peripheral circuits with each other or connects the plurality of peripheral circuits with elements of the memory cell region MEC.

The lower substrate 52 may be configured as a semiconductor substrate. For example, the lower substrate 52 may include Si, Ge, or SiGe. An active region AC may be defined in the lower substrate 52 by a device isolation layer 54. A plurality of transistors TR configuring the plurality of peripheral circuits may be formed on the active region AC. Each of the plurality of transistors TR may include a gate PG and a plurality of ion implantation regions PSD which are formed in the active region AC at two sides of the gate PG. Each of the plurality of ion implantation regions PSD may configure a source region or a drain region of each transistor TR.

The plurality of peripheral circuits included in the peripheral circuit structure PCS may include various circuits that are included in the peripheral circuit 30 that is described above with reference to FIG. 7. In embodiments of the present inventive concept, the plurality of peripheral circuits included in the peripheral circuit structure PCS may include the row decoder 32, the page buffer 34, the data I/O circuit 36, the control logic 38, and the common source line driver 30 each illustrated in FIG. 7.

The multi-layer wiring structure MWS included in the peripheral circuit structure PCS may include a plurality of peripheral circuit wiring layers ML60 to ML62 and a plurality of peripheral circuit contacts MC60 to MC62. At least some of the plurality of peripheral circuit wiring layers ML60 to ML62 may be configured to be electrically connected with a corresponding transistor TR. The plurality of peripheral circuit contacts MC60 to MC62 may connect, with each other, some elements selected from the plurality of transistors TR and the plurality of peripheral circuit wiring layers ML60 to ML62.

The upper substrate 110, the insulation plate 112, the first conductive plate 114, and the second conductive plate 118 may extend in a horizontal direction to cover the peripheral circuit structure PCS.

As illustrated in FIG. 12A, a plurality of through openings 120H passing through the upper substrate 110, the insulation plate 112, and the second conductive plate 118 may be formed in a partial region of the connection region CON. Each of the plurality of through openings 120H may be filled with the insulation plug 120. The plurality of through openings 120H may be disposed at a position overlapping a portion of the peripheral circuit structure PCS in the vertical direction Z. The insulation plug 120 may include, for example, silicon oxide, silicon nitride, or a combination thereof.

In the connection region CON, each of the plurality of memory cell contacts MCC may extend up to the peripheral circuit structure PCS through the through opening 120H and may be configured to be electrically connected with one wiring layer selected from among the plurality of peripheral circuit wiring layers ML60 to ML62. For example, each of the plurality of memory cell contacts MCC may be electrically connected with the peripheral circuit wiring layer ML62 of an uppermost layer, which is closest to the cell array structure CAS, of the plurality of peripheral circuit wiring layers ML60 to ML62.

In the connection region CON, each of the plurality of through vias THV may extend up to the peripheral circuit structure PCS through the through opening 120H and may be configured to be electrically connected with one wiring layer selected from among the plurality of peripheral circuit wiring layers ML60 to ML62. For example, each of the plurality of through vias THV may be electrically connected with the peripheral circuit wiring layer ML62 of the uppermost layer, which is closest to the cell array structure CAS, of the plurality of peripheral circuit wiring layers ML60 to ML62. In this case, a through opening 120H through which the plurality of dummy channel structures D140 pass may be spaced apart from a through opening 120H through which the plurality of through vias THV pass.

Each of the plurality of memory cell contacts MCC and the plurality of through vias THV may be connected with at least one peripheral circuit, selected from among the plurality of peripheral circuits, through the multi-layer wiring structure MWS that is included in the peripheral circuit structure PCS. The plurality of dummy channel structures D140 may extend up to the peripheral circuit structure PCS and may be connected with one wiring layer selected from among the plurality of peripheral circuit wiring layers ML60 to ML62, but might not be connected with the peripheral circuit that is included in the peripheral circuit structure PCS.

In FIGS. 12A and 12B, it is illustrated that the multi-layer wiring structure MWS includes a three-layer wiring layer in the vertical direction Z, but the present inventive concept is not limited to the illustration of FIGS. 12A and 12B. For example, the multi-layer wiring structure MWS may include a two-layer or four or more-layer wiring layer.

Each of the plurality of peripheral circuit wiring layers ML60 to ML62 and the plurality of peripheral circuit contacts MC60 to MC62 may include metal, conductive metal nitride, metal silicide, or a combination thereof. For example, each of the plurality of peripheral circuit wiring layers ML60 to ML62 and the plurality of peripheral circuit contacts MC60 to MC62 may each include a conductive material such as W, Mo, Ti, Co, Ta, Ni, tungsten silicide, titanium silicide, cobalt silicide, tantalum silicide, or nickel silicide.

The plurality of transistors TR and the multi-layer wiring structure MWS each included in the peripheral circuit structure PCS may be covered by the interlayer insulation layer 70. The plurality of through vias THV may pass through a portion of the interlayer insulation layer 70 and may contact an upper surface of the peripheral circuit wiring layer ML62. The plurality of memory cell contacts MCC might not pass through the interlayer insulation layer 70 and may contact the upper surface of the peripheral circuit wiring layer ML62. The interlayer insulation layer 70 may include, for example, silicon oxide, SiON, or SiOCN.

As illustrated in FIG. 12A, a plurality of conductive landing vias 72 spaced apart from one another in a horizontal direction may be disposed in the connection region CON. The plurality of conductive landing vias 72 may be disposed at a position overlapping the through opening 120H in the vertical direction Z, at a level which is higher than a level at which the multi-layer wiring structure MWS is disposed and lower than a level at which the upper substrate 110 is disposed in the vertical direction Z.

The plurality of conductive landing vias 72 may each be disposed between the memory cell contact MCC and the peripheral circuit wiring layer ML62. For example, some of the plurality of conductive landing vias 72 may include an upper surface that contacts the memory cell contact MCC and a lower surface contacts the peripheral circuit wiring layer ML62. Other conductive landing vias 72 of the plurality of conductive landing vias 72 may include an upper surface that contacts at least one of the plurality of dummy channel structures D140. The conductive landing via 72 may be connected with at least one of a plurality of circuits of the peripheral circuit structure PCS through the peripheral circuit wiring layer ML62. However, the conductive landing via 72 may be omitted. In this case, the memory cell contact MCC may directly contact the peripheral circuit wiring layer ML62.

The plurality of through vias THV might not pass through the conductive landing via 72 and may be directly connected with the peripheral circuit wiring layer ML62.

The plurality of conductive landing vias 72 may include a material which differs from that of the plurality of peripheral circuit wiring layers ML60 to ML62 that are included in the peripheral circuit structure PCS. In embodiments of the present inventive concept, the plurality of conductive landing vias 72 might not include metal. In embodiments of the present inventive concept, the plurality of conductive landing vias 72 may include a doped semiconductor material or an undoped semiconductor material. For example, the plurality of conductive landing vias 72 may include doped polysilicon or undoped polysilicon, but the present inventive concept is not limited thereto.

In FIG. 11, a configuration is illustrated where some of the plurality of memory cell contacts MCC, the plurality of dummy channel structures D140, and the plurality of through vias THV are arranged in one row along one straight line in the second horizontal direction Y, but the present inventive concept is not limited thereto. An arrangement structure of each of the memory cell contact MCC, the plurality of dummy channel structures D140, and the plurality of through vias THV may be variously selected within the scope of the present inventive concept.

As illustrated in FIGS. 11 and 12A, the peripheral circuit structure PCS may include an upper interlayer insulation layer 76 disposed on the interlayer insulation layer 70. The upper interlayer insulation layer 76 may cover an upper surface of the interlayer insulation layer 70 and an upper surface of each of the plurality of conductive landing vias 72. The upper interlayer insulation layer 76 may include, for example silicon oxide, SiON, or SiOCN.

Each of the plurality of memory cell contacts MCC, the plurality of dummy channel structures D140, and the plurality of through vias THV may pass through the insulation plug 120 and the upper interlayer insulation layer 76 in the vertical direction Z.

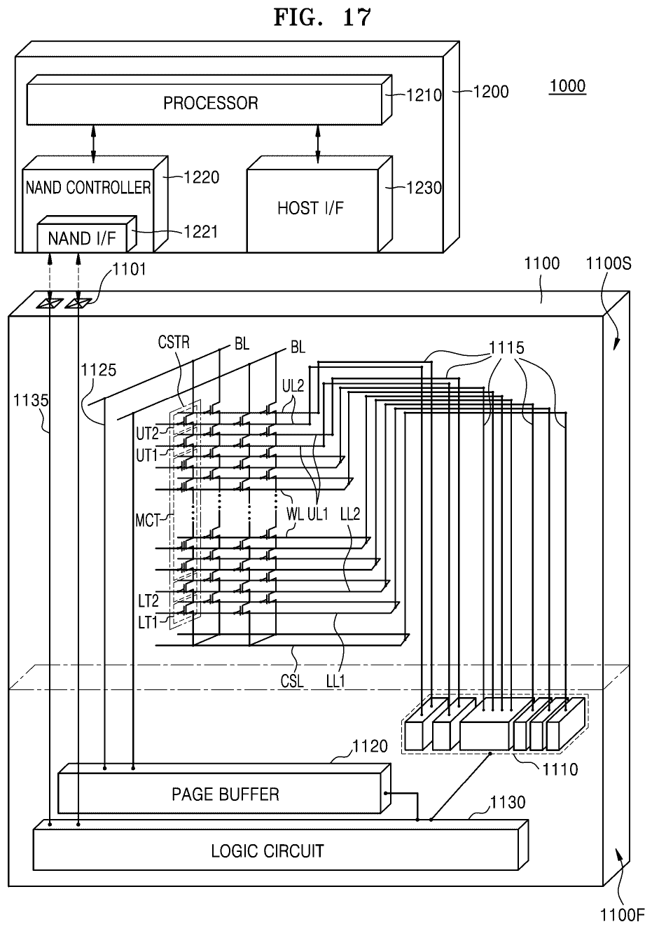

FIG. 17 is a diagram schematically illustrating an electronic system 1000 including a semiconductor device, according to embodiments of the present inventive concept.

Referring to FIG. 17, the electronic system 1000 according to embodiments of the present inventive concept may include a semiconductor device 1100 and a controller 1200 electrically connected with the semiconductor device 1100. The electronic system 1000 may be a storage device including one semiconductor device 1100 or a plurality of semiconductor devices 1100 or an electronic device including the storage device. For example, the electronic system 1000 may be a solid state drive (SSD) device, a universal serial bus (USB), a computing system, a medical device, or a communication device, which includes at least one semiconductor device 1100.

The semiconductor device 1100 may be a non-volatile memory device. For example, the semiconductor device 1100 may be a NAND flash memory device including at least one of the structures of the semiconductor devices 1, 10, and 100 described above with reference to FIGS. 1 to 16. The semiconductor device 1100 may include a first structure 1100F and a second structure 1100S on the first structure 1100F. In embodiments of the present inventive concept, the first structure 1100F may be disposed next to the second structure 1100S. The first structure 1100F may include a peripheral circuit structure including a decoder circuit 1110, a page buffer 1120, and a logic circuit 1130. The second structure 1100S may be a bit line BL, a common source line CSL, a plurality of word lines WL, first and second gate upper lines UL1 and UL2, first and second gate lower lines LL1 and LL2, and a memory cell structure including a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to embodiments of the present inventive concept.

In embodiments of the present inventive concept, the upper transistors UT1 and UT2 may include string selection transistors, and the lower transistors LT1 and LT2 may include ground selection transistors. A plurality of gate lower lines LL1 and LL2 may respectively be gate electrodes of the lower transistors LT1 and LT2. The word line WL may be a gate electrode of the memory cell transistor MCT, and the gate upper lines UL1 and UL2 may be gate electrodes of the upper transistors UT1 and UT2.

The common source line CSL, the plurality of gate lower lines LL1 and LL2, the plurality of word lines WL, and the plurality of gate upper lines UL1 and UL2 may be electrically connected with the decoder circuit 1110 through a plurality of first connection wirings 1115 which extend up to the second structure 1100S from the first structure 1100F. The plurality of bit lines BL may be electrically connected with the page buffer 1120 through a plurality of second connection wirings 1125 which extend up to the second structure 1100S from the first structure 1100F.

In the first structure 1100F, the decoder circuit 1110 and the page buffer 1120 may execute a control operation on at least one of the plurality of memory cell transistors MCT. The decoder circuit 1110 and the page buffer 1120 may be controlled by the logic circuit 1130.

The semiconductor device 1100 may communicate with the controller 1200 through an I/O pad 1101 that is electrically connected with the logic circuit 1130. The I/O pad 1101 may be electrically connected with the logic circuit 1130 through an I/O connection wiring 1135 which extend up to the second structure 1100S from the first structure 1100F.

The controller 1200 may include a processor 1210, a NAND controller 1220, and a host interface 1230. According to embodiments of the present inventive concept, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate based on certain firmware and may control the NAND controller 1220 to access the semiconductor device 1100. The NAND controller 1220 may include a NAND interface 1221 which processes communication with the semiconductor device 1100. A control command for controlling the semiconductor device 1100, data which is to be stored in the plurality of memory cell transistors MCT of the semiconductor device 1100, and data which is to be read from the plurality of memory cell transistors MCT of the semiconductor device 1100 may be transmitted through the NAND interface 1221. The host interface 1230 may provide a communication function between the electronic system 1000 and an external host. When the control command is received from the external host through the host interface 1230, the processor 1210 may control the semiconductor device 1100 in response to the control command.

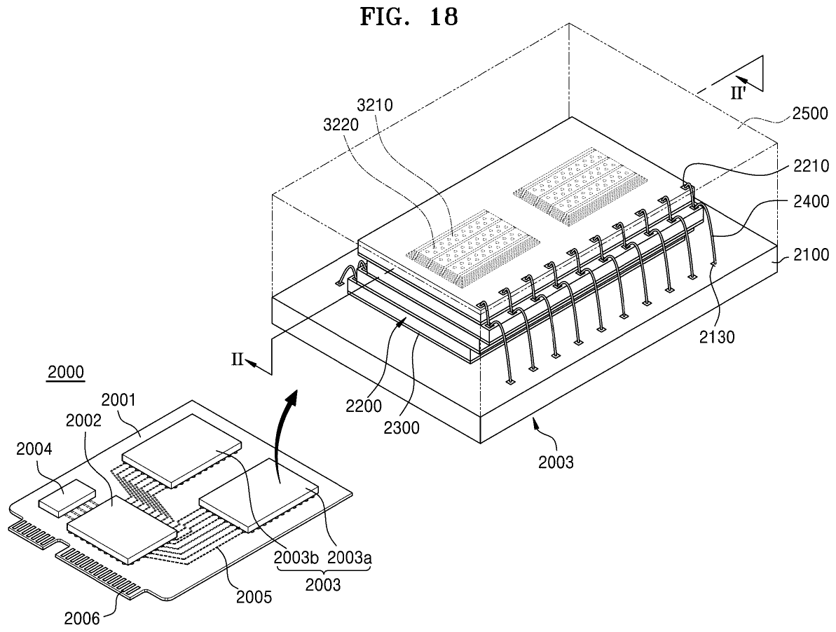

FIG. 18 is a perspective view schematically illustrating an electronic system 2000 including a semiconductor device, according to embodiments of the present inventive concept.

Referring to FIG. 18, the electronic system 2000 according to embodiments of the present inventive concept may include a main substrate 2001, a controller 2002 mounted on the main substrate 2001, one or more semiconductor packages 2003, and dynamic random access memory (DRAM) 2004. The semiconductor package 2003 and the DRAM 2004 may be connected with the controller 2002 by a plurality of wiring patterns 2005 that are formed in the main substrate 2001.

The main substrate 2001 may include a connector 2006 including a plurality of pins coupled to the external host. The number and arrangement of pins in the connector 2006 may be changed based on a communication interface between the electronic system 2000 and the external host. In embodiments of the present inventive concept, the electronic system 2000 may communicate with the external host, based on one of interfaces such as USB, peripheral component interconnection (PCI) express (PIC-E), serial advanced technology attachment (SATA), and M-Phy for universal flash storage (UFS). In embodiments of the present inventive concept, the electronic system 2000 may operate with power supplied from the external host through the connector 2006. The electronic system 2000 may further include a power management integrated circuit (PMIC) which distributes power, which is supplied from the external host, to the controller 2002 and the semiconductor package 2003.

The controller 2002 may store data in the semiconductor package 2003 or may read data from the semiconductor package 2003 and may increase an operation speed of the electronic system 2000.

The DRAM 2004 may be a buffer memory for reducing a speed difference between the external host and the semiconductor package 2003 which is a data storage space. The DRAM 2004 included in the electronic system 2000 may operate as a kind of cache memory and may provide a space for temporarily storing data in a control operation on the semiconductor package 2003. When the electronic system 2000 is included in the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200 on the package substrate 2100, an adhesive layer 2300 disposed on a lower surface of each of the plurality of semiconductor chips 2200, a connection structure 2400 electrically connecting the plurality of semiconductor chips 2200 with the package substrate 2100, and a molding layer 2500 which covers the plurality of semiconductor chips 2200 and the connection structure 2400 on the package substrate 2100.

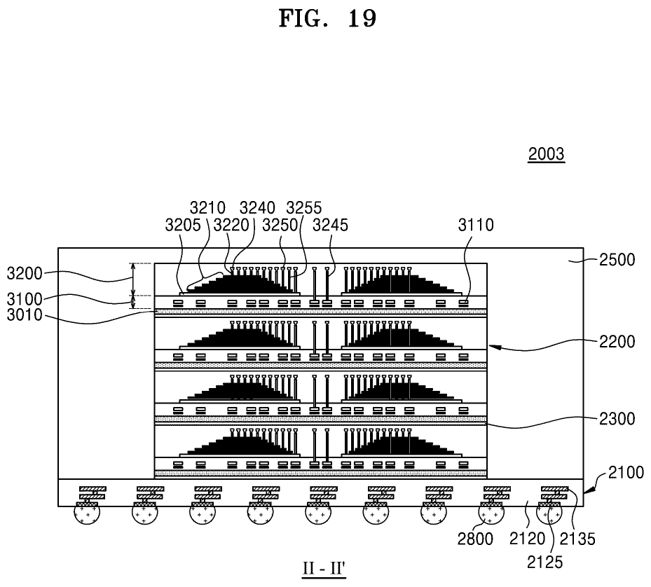

The package substrate 2100 may be a printed circuit board (PCB) including a plurality of package upper pads 2130. Each of the plurality of semiconductor chips 2200 may include an I/O pad 2210. The I/O pad 2210 may correspond to the I/O pad 1101 of FIG. 19. Each of the plurality of semiconductor chips 2200 may include a plurality of gate stacks 3210 and a plurality of channel structures 3220. Each of the plurality of semiconductor chips 2200 may include at least one of the semiconductor devices 1, 10, and 100 that are described above with reference to FIGS. 1 to 16.

In embodiments of the present inventive concept, the connection structure 2400 may be a bonding wire which electrically connects the I/O pad 2210 with the package upper pad 2130. Therefore, in the first and second semiconductor packages 2003a and 2003b, the plurality of semiconductor chips 2200 may be electrically connected with one another by a bonding wire scheme and may be electrically connected with the package upper pad 2130 of the package substrate 2100. In embodiments of the present inventive concept, in the first and second semiconductor packages 2003a and 2003b, the plurality of semiconductor chips 2200 may be electrically connected with one another by a connection structure including a through silicon via (TSV) instead of the connection structure 2400 based on the bonding wire scheme.

In embodiments of the present inventive concept, the controller 2002 and the plurality of semiconductor chips 2200 may be included in one package. In embodiments of the present inventive concept, the controller 2002 and the plurality of semiconductor chips 2200 may be mounted on a separate interposer substrate which differs from the main substrate 2001, and the controller 2002 may be connected with the plurality of semiconductor chips 2200 by a wiring which is formed in the interposer substrate.

FIG. 19 is a cross-sectional view schematically illustrating semiconductor packages 2003 according to embodiments of the present inventive concept. FIG. 19 illustrates in more detail a configuration of a cross-sectional surface taken along line II-II′ of FIG. 18.

Referring to FIG. 19, in the semiconductor package 2003, a package substrate 2100 may be a PCB. The package substrate 2100 may include a package substrate body part 2120, a plurality of package upper pads 2130 (see FIG. 36) disposed on an upper surface of the package substrate body part 2120, a plurality of lower pads 2125 disposed on and/or exposed through a lower surface of the package substrate body part 2120, and a plurality of internal wirings 2135 electrically connecting the plurality of upper pads 2130 with the plurality of lower pads 2125 in the package substrate body part 2120. The plurality of upper pads 2130 may be electrically connected with the plurality of connection structures 2400. The plurality of lower pads 2125 may be connected with the plurality of wiring patterns 2005 on the main substrate 2001 of the electronic system 2000 illustrated in FIG. 36 through a plurality of conductive connection parts 2800.

Each of a plurality of semiconductor chips 2200 may include a semiconductor substrate 3010 and first and second structures 3100 and 3200 sequentially stacked on the semiconductor substrate 3010. The first structure 3100 may include a peripheral circuit region including a plurality of peripheral wirings 3110. The second structure 3200 may include a common source line 3205, a gate stack 3210 that is disposed on the common source line 3205, a channel structure 3220 that passes through the gate stack 3210, and a bit line 3240 electrically connected with the channel structure 3220. The gate stack 3210 may include an insulation layer and a conductive layer, which are alternately and vertically stacked on each other. In embodiments of the present inventive concept, each of the plurality of semiconductor chips 2200 may include a configuration of the semiconductor device 100 that is described above with reference to FIGS. 10 to 16.

Each of the plurality of semiconductor chips 2200 may include a through wiring 3245 which is electrically connected with the plurality of peripheral wirings 3110 of the first structure 3100 and extends into the second structure 3200. The through wiring 3245 may be disposed outside the gate stack 3210. In addition, according embodiments of the present inventive concept, the through wiring 3245 may pass through the gate stack 3210. Each of the plurality of semiconductor chips 2200 may further include an I/O pad (2210 of FIG. 36) electrically connected with the plurality of peripheral wirings 3110 of the first structure 3100.

Each of the plurality of semiconductor chips 2200 may further include a gate contact 3255 which is connected with a conductive layer of the gate stack 3210 of the second structure 3200. The gate contact 3255 may be electrically connected with one of a plurality of conductive layers and may be electrically disconnected from the other conductive layers. An upper metal wiring 3250 may be electrically connected with the gate contact 3255 and the through wiring 3245. The upper metal wiring 3250 may be disposed on an uppermost surface of the gate stack 3210.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device comprising:
a mold structure;
a low aspect ratio via disposed in a first via hole that passes through at least a portion of the mold structure; and
a first high aspect ratio via disposed in a second via hole which passes through at least a portion of the mold structure and is spaced apart from the first via hole in a horizontal direction,
wherein the low aspect ratio via comprises a first seed pattern, which is disposed in the first via hole, and a first conductive pattern that is disposed on the first seed pattern,
wherein the first high aspect ratio via comprises a second seed pattern, which is disposed in the second via hole, a second conductive pattern, which is disposed on the second seed pattern, a deposition inhibition pattern, which covers at least a portion of an inner sidewall of the second conductive pattern, and a third conductive pattern, which covers an inner sidewall of the deposition inhibition pattern, and
wherein the deposition inhibition pattern comprises a material which is less in surface free energy (SFE) than the second conductive pattern.

2. The semiconductor device of claim 1, wherein the deposition inhibition pattern comprises a tapered shape, wherein a width of the deposition inhibition pattern in a horizontal direction is progressively reduced as the deposition inhibition pattern extends downward in a vertical direction with respect to an upper surface of the mold structure.

3. The semiconductor device of claim 2, wherein the deposition inhibition pattern is disposed between an upper surface of the first high aspect ratio via and a first vertical level,
wherein the first vertical level is between the upper surface and a lower surface of the first high aspect ratio via, and
the second conductive pattern and the third conductive pattern are spaced apart from each other with the deposition inhibition pattern disposed therebetween, between the upper surface of the first high aspect ratio via and the first vertical level.

4. The semiconductor device of claim 3, wherein the second conductive pattern contacts the third conductive pattern, between the first vertical level and the lower surface of the first high aspect ratio via.

5. The semiconductor device of claim 1, wherein the deposition inhibition pattern has an annular shape and surrounds the third conductive pattern.

6. The semiconductor device of claim 1, wherein the first seed pattern and the second seed pattern comprise the same material as each other.

7. The semiconductor device of claim 1, wherein the second conductive pattern comprises at least one of tungsten (W), titanium (Ti), aluminum (Al), molybdenum (Mo), tantalum (Ta), palladium (Pd), nickel (Ni), ruthenium (Ru), iridium (Ir), rhodium (Rh), osmium (Os), scandium (Sc), niobium (Nb), copper (Cu), or a combination thereof, and
wherein the deposition inhibition pattern comprises at least one of tungsten nitride (WN), titanium nitride (TiN), aluminum nitride (AlN), tantalum nitride (TaN), molybdenum nitride (MoN), or a combination thereof.

8. The semiconductor device of claim 7, wherein the first conductive pattern and the second conductive pattern comprise the same material as each other.

9. The semiconductor device of claim 1, wherein the deposition inhibition pattern is disposed between an upper surface of the first high aspect ratio via and a first vertical level,
wherein the first vertical level is between the upper surface and a lower surface of the first high aspect ratio via,
wherein a horizontal width of the first high aspect ratio via increases as the first high aspect ratio via extends up to a second vertical level from the upper surface of the first high aspect ratio via, and
wherein the second vertical level is between the first vertical level and the upper surface of the first high aspect ratio via.

10. The semiconductor device of claim 1, wherein the upper surface of the first conductive pattern is substantially coplanar with the upper surface of the deposition inhibition pattern.

11. The semiconductor device of claim 1, wherein the first high aspect ratio via comprises a protrusion portion that is disposed in a groove that is recessed in the horizontal direction from the second via hole, and
wherein the deposition inhibition pattern comprises a portion extending in the horizontal direction toward the groove.

12. A semiconductor device comprising:
an upper substrate;
a memory stack structure including a plurality of gate lines overlapping each other in a vertical direction with respect to an upper surface of the upper substrate;
a channel structure passing through the memory stack structure;
a memory cell contact disposed in a first hole passing through at least one of the plurality of gate lines, wherein the memory cell contact contacts one gate line selected from among the plurality of gate lines in the first hole and is spaced apart from the other gate line except the selected one gate line;
a bit line extending in a horizontal direction on the memory stack structure; and
a stud connecting the channel structure with the bit line,
wherein the stud comprises a first conductive pattern and a first seed pattern surrounding the first conductive pattern,
wherein the memory cell contact comprises a second seed pattern, which is disposed in the first hole, a second conductive pattern, which is disposed on the second seed pattern, a first deposition inhibition pattern, which covers at least a portion of an inner sidewall of the second conductive pattern, and a third conductive pattern, which covers an inner sidewall of the first deposition inhibition pattern, and
wherein the first deposition inhibition pattern comprises a material which is less in surface free energy than the second conductive pattern.

13. The semiconductor device of claim 12, wherein the first deposition inhibition pattern comprises a tapered shape, wherein a width of the first deposition inhibition pattern in a horizontal direction is progressively reduced as the first deposition inhibition pattern extends downward in the vertical direction with respect to an upper surface of the mold structure.

14. The semiconductor device of claim 13, wherein the first deposition inhibition pattern is disposed between an upper surface of a high aspect ratio via of the semiconductor device and a first vertical level,
wherein the first vertical level is between the upper surface and a lower surface of the high aspect ratio via, and
wherein the second conductive pattern and the third conductive pattern are spaced apart from each other with the first deposition inhibition pattern disposed therebetween, between the upper surface of the high aspect ratio via and the first vertical level.

15. The semiconductor device of claim 12, wherein an upper surface of the first conductive pattern is substantially coplanar with an upper surface of the first deposition inhibition pattern.

16. The semiconductor device of claim 12, further comprising a peripheral circuit structure disposed on the upper substrate,
wherein the peripheral circuit structure comprises a lower substrate, a plurality of circuits formed on the lower substrate, and a plurality of wiring layers connected with the plurality of circuits, and
wherein the memory cell contact is connected with one of the plurality of circuits.

17. The semiconductor device of claim 12, further comprising a through via disposed in a second hole that passes through at least one of the plurality of gate lines,
wherein the through via is spaced apart from all of the plurality of gate lines,
wherein the through via comprises a third seed pattern, which covers an inner sidewall of the second hole, a fourth conductive pattern, which covers an inner sidewall of the third seed pattern, a second deposition inhibition pattern, which covers at least a portion of an inner sidewall of the fourth conductive pattern, and a fifth conductive pattern, which covers an inner sidewall of the second deposition inhibition pattern,
wherein the second deposition inhibition pattern comprises a material which is less in surface free energy than the fourth conductive pattern, and
wherein an upper surface of the second deposition inhibition pattern is substantially coplanar with an upper surface of the first deposition inhibition pattern.

18. The semiconductor device of claim 12, wherein the first deposition inhibition pattern has an annular shape and surrounds the third conductive pattern.

19. An electronic system comprising:
a main substrate;
a semiconductor device disposed on the main substrate; and
a controller electrically connected with the semiconductor device on the main substrate,
wherein the semiconductor device comprises:
an upper substrate;
a memory stack structure including a plurality of gate lines overlapping each other in a vertical direction with respect to an upper surface of the upper substrate;
a channel structure passing through the memory stack structure; and
a memory cell contact disposed in a first hole that passes through at least one of the plurality of gate lines, wherein the memory cell contact contacts one gate line selected from among the plurality of gate lines in the first hole and is spaced apart from the other gate line except the selected one gate line,
wherein the memory cell contact comprises a seed pattern, which is disposed in the first hole, a first conductive pattern, which is disposed on the seed pattern, a deposition inhibition pattern, which covers at least a portion of an inner sidewall of the first conductive pattern, and a second conductive pattern, which covers an inner sidewall of the deposition inhibition pattern, and
wherein the deposition inhibition pattern comprises a tapered shape, wherein a width of the deposition inhibition pattern in a horizontal direction is progressively reduced as the deposition inhibition pattern extends downward in the vertical direction with respect to an upper surface of the mold structure.

20. The electronic system of claim 19, wherein each of the first conductive patterns and the second conductive pattern comprises at least one of tungsten (W), titanium (Ti), aluminum (Al), molybdenum (Mo), tantalum (Ta), palladium (Pd), nickel (Ni), ruthenium (Ru), iridium (Ir), rhodium (Rh), osmium (Os), scandium (Sc), niobium (Nb), copper (Cu), or a combination thereof, and
wherein the deposition inhibition pattern comprises at least one of tungsten nitride (WN), titanium nitride (TiN), aluminum nitride (AlN), tantalum nitride (TaN), molybdenum nitride (MoN), or a combination thereof.
